(19) United States
(12) Patent Application Publication
(10) Pub. No.: US 2017/0368736 A1
(43) Pub. Date: Dec. 28, 2017

(54) WHITE POLYESTER FILM AND METHOD FOR MANUFACTURING SAME, SOLAR CELL BACK SHEET, AND SOLAR CELL MODULE

(71) Applicant: FUJIFILM CORPORATION, Tokyo (JP)

(72) Inventors: Kei HARADA, Shizuoka (JP); Shinichi NAKAI, Shizuoka (JP)

(21) Appl. No.: 15/700,204

(22) Filed: Sep. 11, 2017

Related U.S. Application Data
(63) Continuation of application No. PCT/JP2016/058021, filed on Mar. 14, 2016.

(30) Foreign Application Priority Data
Mar. 31, 2015 (JP) 2015-074615

(51) Int. Cl. B29C 55/12; C08J 5/18; H01L 31/049; C08L 67/02

(52) U.S. Cl. CPC B29C 55/12; C08J 5/18; H01L 31/049; C08L 67/02

(57) ABSTRACT

Provided are a white polyester film including a polyester and white particles, in which, at an equivalent of a thickness of 250 μm, a machine stretching direction tear strength F_{MD} is 2.5 to 6.0 N, a transverse stretching direction tear strength F_{TD} is 2.0 to 5.0 N, a ratio of the machine stretching direction tear strength F_{MD} to the transverse stretching direction tear strength F_{TD} is 1.05 to 4.00, and a concentration of terminal carboxyl groups is 5 to 25 equivalents/ton, a method for manufacturing the same, a solar cell back sheet and a solar cell module in which the same white polyester film is used.

### CROSS-REFERENCE TO RELATED APPLICATIONS

This application is a continuation application of International Application No. PCT/JP2016/058021, filed Mar. 14, 2016, the disclosure of which is incorporated herein by reference in its entirety. Further, this application claims priority from Japanese Patent Application No. 2015-074615, filed Mar. 31, 2015, the disclosure of which is incorporated herein by reference in its entirety.

### BACKGROUND OF THE INVENTION

### 1. Field of the Invention

The present disclosure relates to a white polyester film and a method for manufacturing the same, a solar cell back sheet, and a solar cell module.

### 2. Description of the Related Art

Recently, solar cells have been attracting attention as next-generation sustainable energy sources.

Solar cell modules are constituted of members such as a solar cell element, a sealing material that surrounds (seals) the solar cell element, a transparent front substrate disposed on a light-receiving surface side of the solar cell element, and a rear surface protective sheet for a solar cell (also referred to as “solar cell back sheet” or “back sheet”) that protects a side opposite to the light-receiving surface side (rear surface side).

Solar cell modules are used outdoors for a long period of time, and thus the constituent members thereof are required to have weather resistance, that is, durability in natural environments.

For example, JP2012-214726A discloses a polyester film in which, in the infrared absorption spectrum, the ratio of [=a(988 cm⁻¹)/a(795 cm⁻¹)] of the absorption intensity a (988 cm⁻¹) at 988 cm⁻¹ to the absorption intensity a (795 cm⁻¹) at 795 cm⁻¹ is 0.5 or less and the thermal shrinkage rate in the longitudinal direction and the thermal shrinkage rate in a direction orthogonal to the longitudinal direction after a 30-minute heating treatment at 150° C. are 1.0% or less.

In addition, JP2013-49791A discloses a polyester film containing a polyester resin and two or more terminal sealants having different number-average molecular weights by 4,000 or more, in which the retention of the tear strength after a 60-minute thermal treatment at 120° C. and a relative humidity of 100% is 50% or more.

In addition, JP2011-192790A discloses a polyester film for a solar cell made of a biaxial oriented film of polyethylene terephthalate, in which the weight-average molecular weight of the polyethylene terephthalate in the film is 44,000 to 61,000, the concentration of terminal carboxyl groups is 6 to 29 equivalents/ton, the retention of the degree of elongation in the case of aging the film at a temperature of 85° C. and a humidity of 85% RH for 3,000 hours is 50% or more, the thermal shrinkage rates in the longitudinal direction and the width direction in the case of carrying out a thermal treatment at 150° C. for 30 minutes are both −0.1% to 1.5%, the light transmittance of the film at a wavelength of 550 nm is 80% or more, and the tear load is 0.4 N or more.

### SUMMARY OF THE INVENTION

In a case in which designability or light reflectivity as well as weather resistance is improved in films that are used outdoors such as solar cell back sheets, it is effective to use white polyester films including white particles. However, in a case in which white particles are added to polyester films, it is likely that the polyester films are cleaved and peeled off and the adhesiveness degrades.

For example, the polyester films disclosed by JP2012-214726A, JP2013-49791A, and JP2011-192790A are all intended to improve the weather resistance and the like of transparent films, and, in a case in which white polyester films are produced by adding white particles to these polyester films, there is a possibility that the surface layers of the polyester films are cleaved and the adhesiveness becomes insufficient. In addition, in the case of transparent polyester films not including white particles, sufficient adhesiveness can be obtained by trying to find appropriate formulations of, mainly, coated layers; however, in white polyester films including white particles, it is difficult to obtain sufficient adhesiveness only by improving coated layers.

In addition, for example, in a case in which heat fixation temperatures after stretching are increased in manufacturing steps, the orientations of resins are relaxed, and the cleavage strengths of films are improved; however, in a case in which heat fixation temperatures are too high, the degradation of weather resistance attributed to the relaxation of the orientations is accompanied, and thus it is difficult to satisfy both weather resistance and adhesiveness.

The present disclosure has been made in consideration of the above-described circumstances, and an object of the present disclosure is to provide a white polyester film having excellent weather resistance and excellent adhesiveness to other resin layers and a method for manufacturing the same, a solar cell back sheet and a solar cell module which contribute to the achievement of high power generation efficiencies for a long period of time.

In order to achieve the above-described object, the following inventions are provided.

<1> A white polyester film comprising: a polyester; and white particles, in which, at an equivalent of a thickness of 250 μm, a machine stretching direction tear strength F_{MD} is 2.5 to 6.0 N, a transverse stretching direction tear strength F_{TD} is 2.0 to 5.0 N, a ratio of the machine stretching direction tear strength F_{MD} to the transverse stretching direction tear strength F_{TD} is 1.05 to 4.00, and a concentration of terminal carboxyl groups is 5 to 25 equivalents/ton.

<2> The white polyester film according to <1>, in which a peak temperature of tan δ measured using a dynamic viscoelasticity measurement instrument is 122° C. to 133° C.

<3> The white polyester film according to <1> or <2>, in which a content of the white particles is 2% to 10% by mass with respect to a total mass of the film.

<4> The white polyester film according to any one of <1> to <3>, in which an intrinsic viscosity is 0.65 to 0.90 dL/g.

<5> The white polyester film according to any one of <1> to <4>, in which, at an equivalent of a thickness of 250 μm, the transverse stretching direction tear strength F_{TD} is 2.0 to 4.0 N.

<6> The white polyester film according to any one of <1> to <5>, in which the white polyester film is a film roll wound in a roll shape.

<7> A method for manufacturing the white polyester film according to any one of <1> to <6>, comprising: a non-stretched film formation step of forming a non-stretched film by ejecting a molten substance obtained by melting a mixture including a raw material polyester and white particles from a die and landing the molten substance on a cooling roll, in which a difference between an ejection temperature of the molten substance being ejected from the die and a landing point temperature of the cooling roll is 20° C. or less; a stretching step of forming a biaxial stretched film by stretching the non-stretched film cooled using the cooling roll in a machine direction and a transverse direction; and a heat fixation step of heat-fixing the biaxial stretched film at a temperature of Tm−70° C. or higher and Tm−30° C. or lower in a case in which a melting point of the raw material polyester is represented by Tm° C.

<8> A solar cell back sheet comprising: the white polyester film according to any one of <1> to <6>.

<9> A solar cell module comprising: a solar cell element; a sealing material that seals the solar cell element; a front substrate disposed on an outside of the sealing material on a light-receiving surface side of the solar cell element; and a solar cell back sheet including the white polyester film according to any one of <1> to <5> disposed on an outside of the sealing material on a side opposite to the light-receiving surface side of the solar cell element.

According to the present disclosure, a white polyester film having excellent weather resistance and excellent adhesiveness to other resin layers and a method for manufacturing the same, a solar cell back sheet and a solar cell module which contribute to the achievement of high power generation efficiencies for a long period of time.

### BRIEF DESCRIPTION OF THE DRAWINGS

FIG. 1 is a schematic view illustrating an example of a biaxial stretcher that is used to manufacture a stretched white polyester film of the present disclosure.

FIG. 2 is a schematic view illustrating an example of a constitution of a periphery of a die in a melt extruder that is used to manufacture the stretched white polyester film of the present disclosure.

### DESCRIPTION OF THE PREFERRED EMBODIMENTS

Hereinafter, embodiments of the present disclosure will be described, and the following embodiments are simply examples of the present disclosure and do not limit the present disclosure.

Meanwhile, in the present specification, numerical ranges expressed using “to” refer to ranges including the numerical values before and after the “to” as the upper limit value and the lower limit value. In addition, in a case in which a unit is given only to the upper limit value of a numerical range, the lower limit value also has the same unit as the upper limit value.

<White Polyester Film>

A white polyester film of the present disclosure (hereinafter, in some cases, referred to as “polyester film” or “film”) includes a polyester and white particles, at an equivalent of a thickness of 250 μm, the machine stretching direction tear strength F_{MD} is 2.5 to 6.0 N, the transverse stretching direction tear strength F_{TD} is 2.0 to 5.0 N, the ratio (F_{MD}/F_{TD}) of the machine stretching direction tear strength F_{MD} to the transverse stretching direction tear strength F_{TD} is 1.05 to 4.00, and the concentration of terminal carboxyl groups is 5 to 25 equivalents/ton.

As a result of intensive studies in consideration of the above-described object, the present inventors found that the tear strengths in stretching directions of biaxial stretched white polyester films have a close relationship with adhesiveness and weather resistance.

It was found that, in a case in which the white polyester film is adhered to another resin layer such as a sealing material, the white polyester film and the resin layer are likely to peel from each other in the machine stretching direction in the case of manufacturing the white polyester film by means of biaxial stretching. The reason therefore is considered as described below. Since a non-stretched film is pulled in the machine direction (transportation direction) after a molten substance (melt) obtained by kneading and melting raw materials including a polyester and white particles using an extruder is ejected from a die and landed on a cooling roll, the generation and orientation in the machine direction of the spherocrystals of the polyester are accelerated due to the presence of the white particles in this stage, and some of the spherocrystals oriented in the machine direction still remain even after stretching, and thus, relatively, peeling is likely to occur in the machine direction.

Meanwhile, it is considered that, in a case in which the machine stretching direction tear strength F_{MD} and the transverse stretching direction tear strength F_{TD} are respectively in predetermined ranges, the machine stretching direction tear strength F_{MD} is greater than the transverse stretching direction tear strength F_{TD}, and the ratio (F_{MD}/F_{TD}) between these tear strengths is in a range of 1.05 to 4.00, the white polyester film of the present disclosure has adhesiveness and weather resistance in a well-balanced manner.

(Polyester)

The polyester included in the white polyester film of the present disclosure is not particularly limited, and examples thereof include linear saturated polyesters synthesized from an aromatic dibasic acid or an ester-forming derivative thereof and a diol or an ester-forming derivative thereof.

Specific examples thereof include polyethylene terephthalate (PET), polyethylene isophthalate, polybutylene terephthalate (PBT), poly(1,4-cyclohexylene dimethylene terephthalate), polyethylene-2,6-naphthalate (PEN), and the like. Among these, polyethylene terephthalate and polyethylene-2,6-naphthalate are preferred, and polyethylene terephthalate is particularly preferred in terms of the balance between mechanical properties and costs.

The polyester included in the white polyester film of the present disclosure may be a homopolymer or a copolymer.

Meanwhile, the white polyester film of the present disclosure may be a film obtained by blending a small amount of resins other than the polyester such as polyimide as resin components.

(Polyester)

The kind of the polyester included in the stretched white polyester film of the present disclosure is not particularly limited, and well-known polyesters can be used.

Examples thereof include linear saturated polyesters synthesized from an aromatic dibasic acid or an ester-forming derivative thereof and a diol or an ester-forming derivative thereof. Specific examples of the linear saturated polyesters include polyethylene terephthalate, polyethylene isophthalate, polybutylene terephthalate, poly(1,4-cyclohexylene dimethylene terephthalate), polyethylene-2,6-naphthalate, and the like. Among these, polyethylene terephthalate, polyethylene-2,6-naphthalate, poly(1,4-cyclohexylene dimethylene terephthalate), and the like are particularly preferred in terms of the balance between mechanical properties and costs.

The kind of the polyester is not limited to the above-described polyesters, and other polyesters may be used. The other polyesters may be, for example, polyesters synthesized using a dicarboxylic acid component and a diol component, or commercially available polyesters may be used.

In a case in which a polyester is synthesized, the polyester can be obtained by, for example, causing at least one reaction of an esterification reaction and an ester exchange reaction between the dicarboxylic acid component (a) and the diol component (b) using a well-known method.

Examples of the dicarboxylic acid component (a) include dicarboxylic acids and ester derivatives thereof such as aliphatic dicarboxylic acids such as malonic acid, succinic acid, glutaric acid, adipic acid, suberic acid, sebacic acid, dodecanedioic acid, dimer acids, eicosanedioic acid, pimelic acid, azelaic acid, methylmalonic acid, and ethylmalonic acid; alicyclic dicarboxylic acids such as adamantanedicarboxylic acid, norbornene dicarboxylic acid, cyclohexane dicarboxylic acid, and decalin dicarboxylic acid; aromatic dicarboxylic acids such as terephthalic acid, isophthalic acid, phthalic acid, 1,4-naphthalenedicarboxylic acid, 1,5-naphthalenedicarboxylic acid, 2,6-naphthalenedicarboxylic acid, 1,8-naphthalenedicarboxylic acid, 4,4′-diphenyldicarboxylic acid, 4,4′-diphenylether dicarboxylic acid, sodium 5-sulfoisophthalic acid, phenylindane dicarboxylic acid, anthracenedicarboxylic acid, phenanthrene dicarboxylic acid, and 9,9′-bis(4-carboxyphenyl) fluorenic acid.

Examples of the diol component (b) include diol compounds such as aliphatic diols such as ethylene glycol, 1,2-propanediol, 1,3-propanediol, 1,4-butanediol, 1,2-butanediol, and 1,3-butanediol; alicyclic diols such as cyclohexanedimethanol, spiroglycol, and isosorbide; and aromatic diols such as bisphenol A, 1,3-benzenedimethanol, 1,4-benzenedimethanol, and 9,9′-bis(4-hydroxyphenyl)fluorene.

As the dicarboxylic acid component (a), at least one aromatic dicarboxylic acid is preferably used. More preferably, the polyester contains, in the dicarboxylic acid component, an aromatic dicarboxylic acid as a main component. Here, the “main component” means that the fraction of the aromatic dicarboxylic acid in the dicarboxylic acid component is 80% by mass or greater. The polyester may include a dicarboxylic acid component other than the aromatic dicarboxylic acid. Examples of the above-described dicarboxylic acid component include ester derivatives such as aromatic dicarboxylic acids and the like.

As the diol component (b), at least one of aliphatic diols is preferably used. As the aliphatic diol, for example, ethylene glycol can be included and, preferably, ethylene glycol may be included as a main component. Here, the main component means that the fraction of ethylene glycol in the diol component is 80% by mass or greater.

The amount of the aliphatic diol (for example, ethylene glycol) used is preferably in a range of 1.015 mol to 1.50 mol in relation to 1 mol of the aromatic dicarboxylic acid (for example, terephthalic acid) and, as necessary, an ester derivative thereof. The amount of the aliphatic diol (for example, ethylene glycol) used is more preferably in a range of 1.02 mol to 1.30 mol, and still more preferably in a range of 1.025 mol to 1.10 mol. In a case in which the amount of the aliphatic diol used is in a range of 1.015 mol or greater, the esterification reaction favorably proceeds, and, in a case in which the amount of the aliphatic diol used is in a range of 1.50 mol or less, for example, the generation of diethylene glycol as a byproduct due to the dimerization of ethylene glycol is suppressed, and it is possible to favorably maintain a number of characteristics such as melting point, glass transition temperature, crystallinity, heat resistance, hydrolysis resistance, and weather resistance.

In the esterification reaction or the ester exchange reaction, it is possible to use a well-known reaction catalyst. Examples of the reaction catalyst include alkali metal compounds, alkaline-earth metal compounds, zinc compounds, lead compounds, manganese compounds, cobalt compounds, aluminum compounds, antimony compounds, titanium compounds, and phosphorous compounds. Generally, it is preferable to add an antimony compound, a germanium compound, a titanium compound, or the like as a polymerization catalyst in an arbitrary phase ahead of the completion of the manufacturing of the polyester. As the method for adding the above-described compound, in a case in which a germanium compound is used as an example, germanium compound powder is preferably added as it is.

For example, in the esterification reaction step, the aromatic dicarboxylic acid and the aliphatic diol are polymerized in the presence of a catalyst containing a titanium compound. In this esterification reaction, it is preferable to use, as the titanium compound which serves as the catalyst, an organic chelate titanium complex having an organic acid as a ligand and to provide a process for adding at least the organic chelate titanium complex, a magnesium compound, and a pentavalent phosphoric acid ester not having an aromatic ring as a substituent in this order in the step.

Specifically, in the esterification reaction step, in the beginning, the aromatic dicarboxylic acid and the aliphatic diol are mixed with a catalyst containing the organic chelate titanium complex, which is a titanium compound, ahead of the addition of the magnesium compound and the phosphorous compound. The titanium compound such as the organic chelate titanium complex has a strong catalytic activity for the esterification reaction and is thus capable of causing the esterification reaction to favorably proceed. At this time, the titanium compound may be added during the mixing of the aromatic dicarboxylic acid component and the aliphatic diol component, or the aromatic dicarboxylic acid component (or the aliphatic diol component) and the titanium compound may be mixed together, and then the aliphatic diol component (or the aromatic dicarboxylic acid component) may be mixed with the mixture. In addition, the aromatic dicarboxylic acid component, the aliphatic diol component, and the titanium compound may be mixed together at the same time. There is no particular limitation regarding the mixing method, and the components can be mixed together using a well-known method.

Here, during the polymerization of the polyester, the following compound is preferably added.

As a pentavalent phosphorous compound, at least one pentavalent phosphoric acid ester not having an aromatic ring as a substituent is used. Examples thereof include phosphoric acid esters [(OR)₃—P═O; R=an alkyl group having 1 or 2 carbon atoms] having a lower alkyl group having 2 or less carbon atoms as a substituent. Specifically, trimethyl phosphate, triethyl phosphate, and the like are particularly preferred.

The amount of the phosphorus compound added is preferably in a range of 50 ppm to 90 ppm in terms of the P element-equivalent value. The amount of the phosphorous compound is more preferably 60 ppm to 80 ppm, and still more preferably 60 ppm to 75 ppm in terms of the P element-equivalent value.

In a case in which the polyester includes a magnesium compound, the electrostatic application property of the polyester improves.

Examples of the magnesium compound include magnesium salts such as magnesium oxide, magnesium hydroxide, magnesium alkoxides, magnesium acetate, and magnesium carbonate. Among these, magnesium acetate is most preferred from the viewpoint of the solubility in aliphatic diols such as ethylene glycol.

In order to impart a high electrostatic application property, the amount of the magnesium compound added is preferably 50 ppm and more preferably in a range of 50 ppm to 100 ppm in terms of the Mg element-equivalent value. The amount of the magnesium compound added is preferably 60 ppm to 90 ppm and more preferably 70 ppm to 80 ppm in terms of imparting the electrostatic application property in terms of the Mg element-equivalent value.

In the esterification reaction step, it is particularly preferable to add, melt, and polymerize the titanium compound, which is a catalyst component, and the magnesium compound and the phosphorous compound, which are additives, so that a value Z computed from the following expression (i) satisfies the following relational expression (ii). Here, the content of P refers to the amount of phosphorus derived from all phosphorous compounds including the pentavalent phosphoric acid ester not having an aromatic ring, and the content of Ti refers to the amount of titanium derived from all Ti compounds including the organic chelate titanium complex. As described above, in a case in which the joint use of the magnesium compound and the phosphorous compound in a catalyst system including a titanium compound is selected, and the addition timings and addition fractions thereof are controlled, it is possible to obtain a hue with a slight yellow color tone while appropriately maintaining the catalytic activity of the titanium compound at a high level, and to impart heat resistance so that yellow coloration does not easily occur even in a case in which the polyester is exposed to a high temperature during a polymerization reaction, the formation of a film (melting), and the like.

Z=5×(the content of P [ppm]/the atomic weight of P)−2×(the content of Mg [ppm]/the atomic weight of Mg)−4×(the content of Ti [ppm]/the atomic weight of Ti) (i)

0≦Z≦5.0 (ii)

The phosphorous compound does not only act on titanium but also interacts with the magnesium compound, and thus the above-described expressions serve as indexes for quantitatively expressing the balance among these three components.

Expression (i) is an expression that expresses the amount of phosphorus capable of acting on titanium by subtracting the amount of phosphorus acting on magnesium from the amount of all phosphorus capable of reacting with magnesium and titanium. It can be said that, in a case in which the Z value is a positive value, the amount of phosphorus hindering titanium is excessive, and, conversely, in a case in which the Z value is a negative value, the amount of phosphorus necessary to hinder titanium is not sufficient. In the reaction, since a Ti atom, a Mg atom, and a P atom do not have equal valences, weighting is carried out by multiplying the molar numbers of the respective atoms by the valences thereof.

Meanwhile, special synthesis or the like is not required for the synthesis of the polyester, and it is possible to obtain a polyester having a reaction activity required for the reaction and having a color tone and coloration resistance to heat using a titanium compound which is inexpensive and can be easily procured, the phosphorous compound, and the magnesium compound which are described above.

In Expression (ii), from the viewpoint of further improving the color tone and the coloration resistance to heat in a state of maintaining the polymerization reactivity, it is preferable to satisfy 1.0≦Z≦4.0 and it is more preferable to satisfy 1.5≦Z≦3.0.

As a preferred aspect of the esterification reaction step, 1 ppm to 30 ppm of a chelate titanium complex having citric acid or citrate as a ligand is preferably added to the aromatic dicarboxylic acid and the aliphatic diol before the end of the esterification reaction. After that, it is preferable to add 60 ppm to 90 ppm (more preferably 70 ppm to 80 ppm) of a weakly acidic magnesium salt in the presence of the chelate titanium complex and furthermore, after the above-described addition, add 60 ppm to 80 ppm (more preferably 65 ppm to 75 ppm) of the pentavalent phosphoric acid ester not having an aromatic ring as a substituent.

The esterification reaction step can be carried out while removing water or alcohols generated from the reaction outside of the system using a multistage apparatus including at least two reactors coupled in series under a condition in which ethylene glycol is refluxed.

The esterification reaction step may be carried out in a single stage or may be carried out in multiple separated stages.

In a case in which the esterification reaction step is carried out in a single stage, the esterification reaction temperature is preferably 230° C. to 260° C. and more preferably 240° C. to 250° C.

In a case in which the esterification reaction step is carried out in multiple separated stages, the temperature of the esterification reaction in a first reactor is preferably 230° C. to 260° C. and more preferably 240° C. to 250° C., and the pressure is preferably 1.0 kg/cm² to 5.0 kg/cm², and more preferably 2.0 kg/cm² to 3.0 kg/cm². The temperature of the esterification reaction in a second reactor is preferably 230° C. to 260° C. and more preferably 245° C. to 255° C., and the pressure is preferably 0.5 kg/cm² to 5.0 kg/cm², and more preferably 1.0 kg/cm² to 3.0 kg/cm². Furthermore, in a case in which the esterification reaction step is carried out in three or more separated stages, the conditions for the esterification reaction in the intermediate stage are preferably set to conditions between the first reactor and the final reactor.

Meanwhile, a polycondensation reaction of an esterification reaction product generated from the esterification reaction is caused so as to generate a polycondensate. The polycondensation reaction may be caused in a single stage or may be caused in multiple separated stages.

The esterification reaction product such as an oligomer generated from the esterification reaction is subsequently subjected to a polycondensation reaction. This polycondensation reaction can be preferably caused by supplying the esterification reaction product to a multistage polycondensation reactor.

For example, regarding the conditions for the polycondensation reaction caused in three-stage reactors, in the first reactor, the reaction temperature is 255° C. to 280° C. and more preferably 265° C. to 275° C., and the pressure is 100 torr to 10 torr (13.3×10⁻³ MPa to 1.3×10⁻³ MPa), and more preferably 50 torr to 20 torr (6.67×10⁻³ MPa to 2.67×10⁻³ MPa); in the second reactor, the reaction temperature is 265° C. to 285° C. and more preferably 270° C. to 280° C., and the pressure is 20 torr to 1 torr (2.67×10⁻³ MPa to 1.33×10⁻⁴ MPa), and more preferably 10 torr to 3 torr (1.33×10⁻³ MPa to 4.0×10⁻⁴ MPa); and in the third reactor in the final reactor, the reaction temperature is 270° C. to 290° C. and more preferably 275° C. to 285° C., and the pressure is 10 torr to 0.1 torr (1.33×10⁻³ MPa to 1.33×10⁻⁵ MPa), and more preferably 5 torr to 0.5 torr (6.67×10⁻⁴ MPa to 6.67×10⁻⁵ MPa).

To the polyester synthesized as described above, additives such as a photostabilizing agent, an antioxidant, an ultraviolet absorber, a flame retardant, a lubricant (fine particles), a nucleating agent (crystallization agent), and a crystallization inhibitor may be further added.

In the synthesis of the polyester, it is preferable to carry out solid-phase polymerization after the polymerization using the esterification reaction. In a case in which solid-phase polymerization is carried out, it is possible to control the moisture content of the polyester, the degree of crystallization, the acid value of the polyester, that is, the concentration of terminal carboxyl groups in the polyester, and the intrinsic viscosity.

Particularly, in a case in which the solid-phase polymerization is carried out, the concentration of ethylene glycol (EG) gas at the initiation of the solid-phase polymerization is set to be higher than the concentration of the EG gas at the end of the solid-phase polymerization preferably in a range of 200 ppm to 1000 ppm, more preferably 250 ppm to 800 ppm, and still more preferably in a range of 300 ppm to 700 ppm. At this time, the concentration of terminal COOH can be controlled by adjusting the average EG gas concentration (the average of the gas concentrations at the initiation and at the end of the solid-phase polymerization). That is, EG is added and is thus reacted with the terminal COOH, whereby the terminal COOH concentration can be reduced. EG is preferably 100 ppm to 500 ppm, more preferably 150 ppm to 450 ppm, and still more preferably 200 ppm to 400 ppm.

In addition, the temperature of the solid-phase polymerization is preferably 180° C. to 230° C., more preferably 190° C. to 215° C., and still more preferably 195° C. to 209° C.

In addition, the solid-phase polymerization time is preferably 10 hours to 40 hours, more preferably 14 hours to 35 hours, and still more preferably 18 hours to 30 hours.

Here, the polyester preferably has strong hydrolysis resistance. Therefore, the content of carboxyl groups in the polyester is preferably 50 equivalents/t (here, ‘t’ represents ton. Meanwhile, ton is equal to 1000 kg) or less, more preferably 35 equivalents/t or less, and still more preferably 20 equivalents/t or less. In a case in which the content of the carboxyl groups is 50 equivalents/t or less, it is possible to maintain the hydrolysis resistance and to suppress a decrease in strength to a small extent in a case in which the polyester is aged in a hot and humid environment. The lower limit of the content of the carboxyl groups is preferably 2 equivalents/t, more preferably 3 equivalents/t, and still more preferably 3 equivalents/t in terms of maintaining the adhesiveness to a layer (for example, a resin layer) formed in the polyester.

The content of the carboxyl groups in the polyester can be adjusted using the kind of polymerization catalyst, film-forming conditions (film-forming temperature and time), solid-phase polymerization, additives (a terminal-sealing agent and the like), and the like.

(Terminal Sealant)

In a case in which a terminal sealant is added to the white polyester film of the present disclosure, it is possible to further improve hydrolysis resistance (weather resistance).

The content of the terminal sealant which may be included in the white polyester film of the present disclosure is 0.1% to 10% by mass with respect to the total mass of the polyester. The amount of the terminal sealant added is more preferably 0.2% to 5% by mass and still more preferably 0.3% to 2% by mass with respect to the total mass of the polyester included in the polyester film.

Since the hydrolysis of the polyester is accelerated by the catalytic effect of H⁺ generated from the carboxyl groups and the like at molecular terminals, it is effective to add a terminal sealant that reacts with the terminal carboxyl groups in order to improve the hydrolysis resistance (weather resistance).

In a case in which the amount of the terminal sealant added is 0.1% by mass or more with respect to the total mass of the polyester, a weather resistance-improving effect is easily developed, and, in a case in which the amount added is 10% by mass or less, the terminal sealant acting as a plasticizer on the polyester is suppressed, and the degradation of dynamic strength and heat resistance is suppressed.

Examples of the terminal sealant include epoxy compounds, carbodiimide compounds, oxazoline compounds, carbonate compounds, and the like, and carbodiimide compounds having a high affinity to polyethylene terephthalate (PET) and a favorable terminal sealing capability (hereinafter, in some cases, referred to as “carbodiimide” or “carbodiimide terminal sealant”) are preferred.

The terminal sealant (particularly, the carbodiimide terminal sealant) preferably has a high molecular weight. The use of a terminal sealant having a high molecular weight enables the reduction of sublimation during the formation of films by means of melting. The molecular weight of the terminal sealant is preferably 200 to 100,000, more preferably 2,000 to 80,000, and still more preferably 10,000 to 50,000. In a case in which the molecular weight of the terminal sealant (particularly, the carbodiimide terminal sealant) is in a range of 200 to 100,000, the terminal sealant is easily uniformly dispersed in the polyester, and it becomes easy to sufficiently develop the weather resistance-improving effect. In addition, the terminal sealant is not easily extruded and does not easily sublime during the formation of films, and it becomes easy to develop the weather resistance-improving effect.

Meanwhile, the molecular weight of the terminal sealant refers to the weight-average molecular weight.

Carbodiimide-Based Terminal Sealant:

As carbodiimide compounds having a carbodiimide group, there are monofunctional carbodiimides and multifunctional carbodiimide, and examples of the monofunctional carbodiimides include dicyclohexylcarbodiimide, diisopropylcarbodiimide, dimethylcarbodiimide, diisobutylcarbodiimide, dioctylcarbodiimide, t-butylisopropylcarbodiimide, diphenylcarbodiimide, di-t-butylcarbodiimide, di-β-naphtylcarbodiimide, and the like. Dicyclohexylcarbodiimide and diisopropylcarbodiimide are particularly preferred.

As the multifunctional carbodiimides, carbodiimides having a degree of polymerization of 3 to 15 are preferably used. Specific examples thereof include 1,5-naphthalene carbodiimide, 4,4′-diphenylmethane carbodiimide, 4,4′-diphenyl dimethyl methane carbodiimide, 1,3-phenylene carbodiimide, 1,4-phenylene diisocyanate, 2,4-tolylene carbodiimide, 2,6-tolylene carbodiimide, mixtures of 2,4-tolylene carbodiimide and 2,6-tolylene carbodiimide, hexamethylene carbodiimide, cyclohexane-1,4-carbodiimide, xylylene carbodiimide, isophorone carbodiimide, dicyclohexylmethane-4,4′-carbodiimide, methylcyclohexane carbodiimide, tetramethylxylylene carbodiimide, 2,6-diisopropylphenyl carbodiimide, 1,3,5-triisopropyl benzene-2,4-carbodiimide, and the like.

Since isocyanate-based gas is generated due to thermal decomposition, the carbodiimide compound is preferably a highly thermally resistant carbodiimide compound. In order to enhance thermal resistance, the molecular weight (the degree of polymerization) is preferably high, and it is more preferable to provide a highly thermally resistant structure to the terminals of the carbodiimide compound. In addition, once thermal decomposition occurs, additional thermal decomposition is more likely to occur, and thus it is necessary to find appropriate means for lowering the extrusion temperature of the polyester as much as possible.

The carbodiimide in the terminal sealant is also preferably a carbodiimide having a ring structure (for example, the carbodiimide having a ring structure described in JP2011-153209A). Carbodiimides having a ring structure develop the equivalent effect as the above-described carbodiimide having a high molecular weight even in the case of having a low molecular weight. This is because the terminal carboxyl groups in the polyester and the cyclic carbodiimide cause a ring-opening reaction, one end of the cyclic carbodiimide reacts with the polyester, the ring-opened other end of the carbodiimide reacts with another polyester, and thus the molecular weight increases, which suppresses the generation of isocyanate-based gas.

Among the carbodiimides having a ring structure, in the present disclosure, the terminal sealant is preferably a carbodiimide compound having a ring structure which has carbodiimide groups and in which a first nitrogen atom and a second nitrogen atom are bonded together through a bonding group. Furthermore, the terminal sealant is more preferably a carbodiimide having a ring structure which has at least one carbodiimide group adjacent to an aromatic ring and in which the first nitrogen atom and the second nitrogen atom in the carbodiimide group adjacent to the aromatic ring are bonded together through a bonding group (also referred to as the aromatic cyclic carbodiimide).

The aromatic cyclic carbodiimide may have a plurality of cyclic structures.

The aromatic cyclic carbodiimide may be an aromatic carbodiimide not having a ring structure in which the first nitrogen atoms and the second nitrogen atoms in two or more carbodiimide groups are bonded together through linking groups in the molecule. That is, an aromatic carbodiimide which is a monocycle can be preferably used.

The ring structure has one carbodiimide group (—N═C═N—), and the first nitrogen atom and the second nitrogen atom are bonded together through a bonding group. In a single ring structure, there is only one carbodiimide group; however, for example, in the case of a spirocycle or the like having a plurality of ring structures in the molecule, the compound may have a plurality of carbodiimide groups as long as individual ring structures bonded to spiro atoms have one carbodiimide group. The number of atoms in the ring structure is preferably 8 to 50, more preferably 10 to 30, still more preferably 10 to 20, and particularly preferably 10 to 15.

Here, the number of atoms in the ring structure refers to the number of atoms directly constituting the ring structure, and, for example, the number of atoms constituting the ring structure of an 8-membered ring is 8, and the number of atoms of a 50-membered ring is 50. In a case in which the number of atoms in the ring structure is 8 or more, the stability of the cyclic carbodiimide compound enhances, and it becomes easy to store and use the cyclic carbodiimide compound. There is no particular limitation regarding the upper limit value of the number of ring members from the viewpoint of reactivity, but the difficulty of the synthesis of a cyclic carbodiimide compound having 50 or less atoms is small, and the cost is suppressed at a low level. From the above-described viewpoint, the number of atoms in the ring structure is preferably selected from 10 to 30, more preferably selected from 10 to 20, and particularly preferably selected from a range of 10 to 15.

Specific examples of a carbodiimide-based terminal sealant having a ring structure include the following compounds. However, the present disclosure is not limited by the following specific examples.

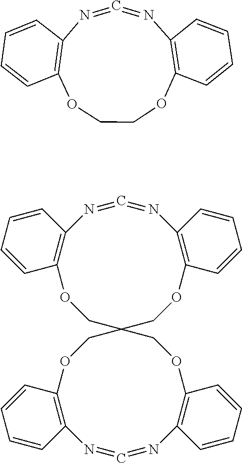 [SMILES: C1=Nc2ccccc2OCCOc2ccccc2N=1 ; C1=Nc2ccccc2OCC2(COc3ccccc3N=1)COc1ccccc1N=C=Nc1ccccc1OC2]

Epoxy-Based Terminal Sealant:

Preferred examples of the epoxy compounds include glycidyl ester compounds, glycidyl ether compounds, and the like.

Specific examples of the glycidyl ester compounds include benzoic acid glycidyl ester, t-Bu-benzoic acid glycidyl ester, p-toluic acid glycidyl ester, cyclohexane carboxylic acid glycidyl ester, pelargonic acid glycidyl ester, stearic acid glycidyl ester, lauric acid glycidyl ester, palmitic acid glycidyl ester, behenic acid glycidyl ester, versatic acid glycidyl ester, oleic acid glycidyl ester, linoleic acid glycidyl ester, linolenic acid glycidyl ester, behenolic acid glycidyl ester, stearolic acid glycidyl ester, terephthalic acid diglycidyl ester, isophthalic acid diglycidyl ester, phthalic acid diglycidyl ester, naphthalene dicarboxylic acid diglycidyl ester, methyl terephthalate diglycidyl ester, hexahydrophthalic acid diglycidyl ester, tetrahydrophthalic acid diglycidyl ester, cyclohexane dicarboxylic acid diglycidyl ester, adipic acid diglycidyl ester, succinic acid diglycidyl ester, sebacic acid diglycidyl ester, dodecanedioic acid diglycidyl ester, octadecane dicarboxylic acid diglycidyl ester, trimellitic acid triglycidyl ester, pyromellitic acid tetraglycidyl ester, and the like, and one or more glycidyl ester compounds can be used.

Specific examples of the glycidyl ether compounds include phenyl glycidyl ether, o-phenyl glycidyl ether, 1,4-bis(β,γ-epoxypropoxy)butane, 1,6-bis(β,γ-epoxypropoxy)hexane, 1,4-bis(β,γ-epoxypropoxy)benzene, 1-(β,γ-epoxypropoxy)-2-ethoxyethane, 1-(β,γ-epoxypropoxy)-2-benzyloxyethane, bisglycidyl polyethers obtained from a reaction between bisphenol and epichlorohydrin such as 2,2-bis-[p-(β,γ-epoxyphenyl)phenyl]propane, 2,2-bis-(4-hydroxyphenyl)propane, and 2,2-bis-(4-hydroxyphenyl)methane, and the like, and one or more glycidyl ether compounds can be used.

Oxazoline-Based Terminal Sealant:

The oxazoline compound is preferably a bisoxazoline compound, and specific examples thereof include 2,2′-bis(2-oxazoline), 2,2′-bis(4-methyl-2-oxazoline), 2,2′-bis(4,4-dimethyl-2-oxazoline), 2,2′-bis(4-ethyl-2-oxazoline), 2,2′-bis(4,4′-diethyl-2-oxazoline), 2,2′-bis(4-propyl-2-oxazoline), 2,2′-bis(4-butyl-2-oxazoline), 2,2′-bis(4-hexyl-2-oxazoline), 2,2′-bis(4-phenyl-2-oxazoline), 2,2′-bis(4-cyclohexyl-2-oxazoline), 2,2′-bis(4-benzyl-2-oxazoline), 2,2′-p-phenylene bis(2-oxazoline), 2,2′-m-phenylene bis(2-oxazoline), 2,2′-o-phenylene bis(2-oxazoline), 2,2′-p-phenylene bis(4-methyl-2-oxazoline), 2,2′-p-phenylene bis(4,4-dimethyl-2-oxazoline), 2,2′-m-phenylene bis(4-methyl-2-oxazoline), 2,2′-m-phenylene bis(4,4-dimethyl-2-oxazoline), 2,2′-ethylene bis(2-oxazoline), 2,2′-tetramethylene bis(2-oxazoline), 2,2′-hexamethylene bis(2-oxazoline), 2,2′-octamethylene bis(2-oxazoline), 2,2′-decamethylene bis(2-oxazoline), 2,2′-ethylene bis(4-methyl-2-oxazoline), 2,2′-tetramethylene bis(4,4-dimethyl-2-oxazoline), 2,2′-9,9′-diphenoxyethane bis(2-oxazoline), 2,2′-cyclohexylene bis(2-oxazoline), 2,2′-diphenylene bis(2-oxazoline), and the like. Among these, 2,2′-bis(2-oxazoline) is most preferably used from the viewpoint of the reactivity with the polyester. Furthermore, the bisoxazoline compounds described above may be used singly or two or more bisoxazoline compounds may be jointly used as long as the object of the present disclosure is achieved.

Even in a case in which the terminal sealant is added to, for example, a resin layer on the polyester film, the terminal sealant does not react with the polyester, and thus it is necessary to knead the terminal sealant and cause the terminal sealant to directly react with polyester molecules in the case of manufacturing the polyester film.

(White Particles)

The white polyester film of the present disclosure contains white particles. The white particles included in the white polyester film are capable of imparting light reflectivity or designability to the film.

The white particles included in the white polyester film of the present disclosure may be any of inorganic particles or organic particles, or both particles may be jointly used.

As the inorganic particles, it is possible to use, for example, wet silica, dry silica, colloidal silica, calcium carbonate, aluminum silicate, calcium phosphate, alumina, magnesium carbonate, zinc carbonate, titanium oxide, zinc oxide (also referred to as Chinese white), antimony oxide, cerium oxide, zirconium oxide, tin oxide, lanthanum oxide, magnesium oxide, barium carbonate, zinc carbonate, lead carbonate basic (also referred to as lead white), barium sulfate, calcium sulfate, lead sulfate, zinc sulfate, mica, titanium dioxide, talc, clay, kaolin, lithium fluoride, calcium fluoride, and the like.

In addition, the surfaces of the white particles may be treated with an inorganic material such as alumina or silica or may be treated with an organic material such as a silicon-based material or an alcohol-based material.

Among these white particles, titanium dioxide and barium sulfate are preferred, and titanium dioxide particles are particularly preferred. In the case of including titanium dioxide particles, the white polyester film of the present disclosure is capable of exhibiting excellent durability even under light irradiation.

As titanium dioxide, there are rutile-type titanium dioxide and anatase-type titanium dioxide, and the white polyester film of the present disclosure preferably includes titanium dioxide particles which mainly include rutile-type titanium dioxide. Here, “mainly” indicates that the amount of the rutile-type titanium dioxide in all of the titanium dioxide particles exceeds 50% by mass.

Light rays in the ultraviolet range barely contribute to the power generation of solar cells, and thus the ultraviolet spectral reflectivity of the white particles is desirably high from the viewpoint of preventing the deterioration of the polyester by ultraviolet rays. Rutile-type titanium dioxide has an extremely high ultraviolet spectral reflectivity, but anatase-type titanium dioxide has a characteristic of a high ultraviolet absorbance (a low spectral reflectivity). Due to the difference in the above-described spectral characteristic attributed to the crystal format of titanium dioxide, the use of the ultraviolet absorption performance of rutile-type titanium dioxide enables the improvement of light resistance in, for example, polyester films for protecting solar cell rear surfaces (solar cell back sheets). In addition, in a case in which the ultraviolet absorption performance of rutile-type titanium dioxide is used, film durability under light irradiation is excellent even without the substantial addition of other ultraviolet absorbents. Therefore, contamination and the degradation of adhesiveness caused by the bleed-out of ultraviolet absorbents are not easily caused.

The content of anatase-type titanium dioxide in the titanium dioxide particles included in the white polyester film of the present disclosure is preferably 10% by mass or less, more preferably 5% by mass or less, and particularly preferably 0% by mass. In a case in which the content of anatase-type titanium dioxide in the titanium dioxide particles included in the white polyester film of the present disclosure is 10% by mass or less, the amount of rutile-type titanium dioxide in all of the titanium dioxide particles relatively increases, and thus the ultraviolet absorption performance becomes sufficient, and additionally, it is possible to suppress the degradation of light resistance caused by the strong photocatalytic action of the anatase-type titanium dioxide. Rutile-type titanium dioxide and anatase-type titanium dioxide can be differentiated from each other by X-ray structural diffraction or spectral absorption characteristics.

The surfaces of the rutile-type titanium dioxide particles may be treated with an inorganic material such as alumina or silica or may be treated with an organic material such as a silicon-based material or an alcohol-based material.

Before the rutile-type titanium dioxide particles are blended into the polyester, the adjustment of particle diameters and the removal of coarse particles may be carried out using purification processes. Regarding industrial means for the purification processes, for example, jet milling and ball milling can be applied as crushing means, and, for example, dry-type or wet-type centrifugal separation can be applied as classification means.

The white polyester film of the present disclosure may contain organic particles as the white particles. The organic particles are preferably particles capable of withstanding heat during the formation of the polyester film, and, for example, white particles made of a crosslinking-type resin can be used. Specifically, polystyrene crosslinked with divinylbenzene and the like can be used.

The content of the white particles in the white polyester film of the present disclosure is preferably 2% to 10% by mass of the entire mass of the film. In a case in which the content of the white particles in the white polyester film of the present disclosure is 2% by mass or more, a high light reflectivity can be obtained, and, in a case in which the content is 10% by mass or less, favorable weather resistance and adhesiveness can be obtained.

From the above-described viewpoint, the content of the white particles in the white polyester film of the present disclosure is more preferably 2% to 8% by mass and still more preferably 3% to 6% by mass.

The white polyester film of the present disclosure may contain one or more kinds of white particles. In a case in which two or more kinds of white particles are included, the total content of the white particles is preferably set to 2% to 10% by mass.

The content of the white particles included in the white polyester film can be measured using the following method.

3 g of the film is placed in a crucible as a measurement specimen and is heated at 900° C. for 120 minutes in an electric oven. After that, the crucible is removed while cooling the measurement specimen in the electric oven, and the mass of ash remaining in the crucible is measured. This ash is the component of the white particles, and a value obtained by dividing the mass of the ash by the mass of the measurement specimen and multiplying the result by 100 is used as the content (% by mass) of the white particles.

Meanwhile, in the case of before the manufacturing of the film, the content may be obtained from the amount of the white particles (white pigment), which are used as a raw material, added.

The average particle diameter of the white particles is preferably 0.03 to 0.25 μm, more preferably 0.07 to 0.25 μm, and still more preferably 0.1 to 0.2 μm. In a case in which the average particle diameter of the particles is 0.03 to 0.25 μm, it is possible to effectively reflect light in the visible light range through the near-infrared range which is particularly effective for power generation.

The average particle diameter of the white particles included in the white polyester film of the present disclosure is obtained using a method in which an electronic microscope is used. Specifically, the average particle diameter is obtained using the following method.

The white particles on a cross-section of the film in the thickness direction are observed using a scanning electron microscope, the magnification is appropriately changed depending on the sizes of the particles, and a photograph of the white particles is captured and enlarged. For at least 200 randomly-selected particles, the outer peripheries of the respective particles are traced. The circle-equivalent diameters of the particles are measured from these traced images in an image analysis device, and the average value thereof is considered as the average particle diameter.

Meanwhile, in the case of before the manufacturing of the film, for at least 200 randomly-selected particles out of the white particles (white pigment) that are used as a raw material, the average particle diameter may be obtained in the same manner.

The surfaces of rutile-type titanium oxide particles may be treated with an inorganic material such as alumina or silica or may be treated with an organic material such as a silicon-based material or an alcohol-based material. Before the rutile-type titanium oxide particles are blended into the polyester, the adjustment of particle diameters and the removal of coarse particles may be carried out using purification processes. Regarding industrial means for the purification processes, for example, jet milling and ball milling can be applied as crushing means, and, for example, dry-type or wet-type centrifugal separation can be applied as classification means.

(Tear Strength)

In the white polyester film of the present disclosure, at an equivalent of a thickness of 250 μm, the machine stretching direction tear strength F_{MD} is 2.5 to 6.0 N, the transverse stretching direction tear strength F_{TD} is 2.0 to 5.0 N, and the ratio of the machine stretching direction tear strength F_{MD} to the transverse stretching direction tear strength F_{TD} is 1.05 to 4.00.

Machine Stretching Direction Tear Strength F_{MD}

In the white polyester film of the present disclosure, in a case in which the machine stretching direction tear strength F_{MD} at an equivalent of a thickness of 250 μm is 2.5 N or more, the adhesiveness is favorable, and, in a case in which the machine stretching direction tear strength F_{MD} is 6.0 N or less, the generation of cracks during the cutting of the film is suppressed, and the weather resistance can be improved.

From such a viewpoint, the machine stretching direction tear strength F_{MD} at an equivalent of a thickness of 250 μm is preferably 2.5 to 5.5 N and more preferably 3.0 to 5.0 N.

Transverse Stretching Direction Tear Strength F_{TD}

In the white polyester film of the present disclosure, in a case in which the transverse stretching direction tear strength F_{TD} at an equivalent of a thickness of 250 μm is 2.0 or more, the adhesiveness is favorable, and, in a case in which the transverse stretching direction tear strength F_{TD} is 5.0 N or less, the generation of cracks during the cutting of the film is suppressed.

From such a viewpoint, the transverse stretching direction tear strength F_{TD} at an equivalent of a thickness of 250 μm is preferably 2.0 to 4.5 N and more preferably 2.0 to 4.0 N. Particularly, in a case in which the transverse stretching direction tear strength F_{TD} is set in a range of 2.0 to 4.0 N, it is also possible to improve the weather resistance.

Tear Strength Ratio Between MD and TD

In a case in which the ratio (F_{MD}/F_{TD}) of the machine stretching direction tear strength F_{MD} to the transverse stretching direction tear strength F_{TD} is 1.05 or more, sufficient weather resistance can be obtained, and, in a case in which the ratio is 4.00 or less, sufficient adhesiveness to different kinds of materials such as other resin layers can be obtained. In the white polyester film of the present disclosure, even in a case in which the machine stretching direction tear strength F_{MD} is 2.5 to 6.0 N and the transverse stretching direction tear strength F_{TD} is 2.0 to 5.0 N at an equivalent of a thickness of 250 μm, at a tear strength ratio of less than 1.05, the weather resistance becomes insufficient, and, at a tear strength ratio of more than 4.00, the adhesiveness becomes insufficient.

From such a viewpoint, the tear strength ratio between MD and TD (F_{MD}/F_{TD}) is preferably 1.05 to 3.00 and more preferably 1.05 to 2.50.

Regarding the tear strengths in the respective directions, the machine stretching direction tear strength F_{MD} tends to improve in a case in which the difference between the ejection temperature from a die and the temperature of a landing point on a cooling roll in a non-stretched film formation step is decreased, and the transverse stretching direction tear strength F_{TD} tends to improve in a case in which the heat fixation temperature is increased. The details will be described in the section of the manufacturing method.

The tear strengths of the white polyester film of the present disclosure are measured using the following method.

<Measurement Method>

A 2 cm-wide (short side)×10 cm-long (long side) sample film is cut out in the MD and TD directions respectively.

A 5 cm-long notch is provided parallel to the long side direction at the center of the short side, and the stress at the notch is measured using a tensile tester and the following method. Meanwhile, the stress is measured at 25° C. and a relative humidity of 50%.

(1-1) One end of the notched portion is held at one chuck of the tensile tester, and the other end is held at the other chuck.

(1-2) The chucks are pulled at 30 mm/minute, and the tensile stress is measured. As the distance between the chucks increases, the stress increases, and a flat portion appears. The stress in the flat portion is considered as the tear strength, the tear strength is measured three times (n=3), and the average value thereof is obtained.

(1-3) This measurement is carried out in MD and TD respectively, and the average values at an equivalent of a thickness of 250 μm are obtained in the respective directions and are considered as the tear strengths in the respective directions.

Meanwhile, in a case in which the thickness of the sample film is represented by t μm, and the tear strength is represented by F, the tear strength at an equivalent of a thickness of 250 can be obtained as (F/t)×250.

Meanwhile, in a case in which the film manufactured by steps such as biaxial stretching is wound to a film roll state, the circumferential direction (transportation direction) of the roll is considered as MD, and the width direction is considered as TD.

In addition, generally, the film manufactured by means of biaxial stretching or the like is not relaxed in the MD direction, and thus it is possible to specify MD and TD by considering a direction in which the thermal shrinkage rate is large as MD.

(Concentration of Terminal Carboxyl Groups)

In the white polyester film of the present disclosure, the concentration of the terminal carboxyl groups is preferably 5 to 25 equivalents/ton. The concentration of the terminal carboxyl groups is also referred to as the acid value and is expressed as “AV” in some cases. Meanwhile, in the present specification, “equivalents/ton” represents the molar equivalents per ton and is expressed as “eq/t” in some cases.

In a case in which the concentration of the terminal carboxyl groups in the polyester film is 5 equivalents/ton or more, the number of carboxyl groups (COOH groups) on the surface does not become too small (that is, the polarity does not become too low), and the polyester film is capable of having favorable adhesiveness to different kinds of materials such as other resin layers.

Meanwhile, H⁺ in the COOH groups at the polyester molecular terminals acts as a catalyst and accelerates hydrolysis. In a case in which the concentration of the terminal carboxyl groups in the polyester film is 25 equivalents/ton or less, it is possible to suppress the degradation of hydrolysis resistance.

From the viewpoint of improving the adhesiveness to different kinds of materials such as other resin layers and improving the hydrolysis resistance, the concentration of the terminal carboxyl groups in the white polyester film of the present disclosure is more preferably 10 to 25 equivalents/ton and still more preferably 15 to 25 equivalents/ton.

The concentration of the terminal carboxyl groups is a value measured using the following method. That is, 0.1 g of a resin measurement sample is dissolved in 10 mL of benzyl alcohol, furthermore, chloroform is added thereto so as to obtain a solution mixture, and a phenol red indicator is added dropwise to the solution mixture. This solution is titrated with a reference liquid (0.01 mol/L KOH-benzyl alcohol solution mixture), and the concentration of the terminal carboxyl groups is obtained from the titration amount.

(Peak Temperature of tan δ)

In the white polyester film of the present disclosure, the peak temperature of tan δ measured using a dynamic viscoelasticity measurement instrument is preferably 122° C. to 135° C.

In a case in which the peak temperature of tan δ measured using a dynamic viscoelasticity measurement instrument is 122° C. or higher, it is possible to improve the weather resistance, and, in a case in which the peak temperature is 135° C. or lower, it is possible to improve the adhesiveness. From such a viewpoint, in the white polyester film of the present disclosure, the peak temperature of tan δ is more preferably 122° C. to 130° C. and particularly preferably 122° C. to 128° C.

The peak temperature of tan δ of the white polyester film can be adjusted using the kinds of polymerization catalysts before the formation of films, ordinary solid phase polymerization conditions after polymerization, film formation conditions (film formation temperatures, times, stretching conditions, and heat relaxation conditions), and the like. The peak temperature is particularly preferably controlled using stretching conditions (stretch ratios and heat fixation temperatures) which are adjustable online.

The peak temperature of tan δ is a value measured using a commercially available dynamic viscoelasticity measurement instrument (VIBRON: DVA-225, manufactured by IT Keisoku Seigyo Corporation, Osaka, Japan) under conditions of a temperature-increase rate of 2° C./minute, a measurement temperature range of 30° C. to 200° C., and a frequency of 1 Hz after the humidity is adjusted at 25° C. and a relative humidity of 60% for two or more hours.

(Intrinsic Viscosity)

In the white polyester film of the present disclosure, the intrinsic viscosity (IV) of the film is preferably 0.65 to 0.90 dL/g.

In a case in which IV of the film is 0.65 dL/g or more, sufficient weather resistance can be obtained. On the other hand, in a case in which IV of the film is 0.90 dL/g or less, in the case of manufacturing the film, the extrusion of a molten substance (melt) in the non-stretched film formation step is easy, additionally, shear heat generation is suppressed, and the degradation of hydrolysis resistance is suppressed.

From such a viewpoint, IV of the film is more preferably 0.65 to 0.85 dL/g and still more preferably 0.67 to 0.77 dL/g.

As the method for measuring IV of the white polyester film of the present disclosure, a method described in examples is used.

(Thickness)

The thickness of the white polyester film of the present disclosure is preferably 220 to 450 μm. In a case in which the thickness of the film is 250 μm or more, the film is capable of having favorable voltage resistance. Meanwhile, in a case in which the thickness of the film is 500 μm or less, the degradation of hydrolysis resistance due to the degradation of the temperature increase cooling capability of the film during the formation of the film is suppressed, and it is possible to stretch the film without applying high loads to stretchers during the stretching of the film.

From such a viewpoint, the thickness of the film is preferably 250 to 350 μm.

As the method for measuring the thickness of the white polyester film of the present disclosure, a method described in examples is used.

(Surface Treatment)

In order to further improve the adhesiveness to different kinds of materials, surface treatments such as a corona treatment, a flame treatment, and a glow discharge treatment may be carried out on the white polyester film of the present disclosure.

In the corona discharge treatment, a high frequency and a high voltage are applied between a metallic roll which is generally coated with a dielectric body (dielectric roll) and an insulated electrode so as to cause the insulation breakdown of air between electrodes, whereby the air between the electrodes is ionized and corona discharge is generated between the electrodes. In addition, the surface treatment is carried out by passing the polyester film through between the corona discharges.

Regarding treatment conditions used in the present disclosure, it is preferable that the gap clearance between the electrode and the dielectric roll is 1 mm to 3 mm, the frequency is 1 kHz to 100 kHz, and the applied energy is approximately 0.2 kV·A·minutes/m² to 5 kV·A·minutes/m².

The glow discharge treatment is a method which is also called a vacuum plasma treatment or a low-pressure plasma treatment and in which plasma is generated through discharging in a gas in a low-pressure atmosphere (plasma gas), thereby treating the surface of a film. Low-pressure plasma used in the glow discharge treatment of the present disclosure is non-equilibrium plasma generated under conditions in which the pressure of the plasma gas is low. The glow discharge treatment of the polyester film is carried out by placing a film to be treated (polyester film) in this low-pressure plasma atmosphere.

As the method for generating plasma in the glow discharge treatment, it is possible to use a method of direct-current glow discharge, high-frequency discharge, microwave discharge, or the like. The power supply used for the discharge may be a direct current or an alternating current. In a case in which an alternating current is used, the frequency is preferably in a range of approximately 30 Hz to 20 MHz.

In a case in which an alternating current is used, a commercial frequency of 50 Hz or 60 Hz may be used or a high frequency of approximately 10 kHz to 50 kHz may be used. In addition, a method of using a high frequency of 13.56 MHz is also preferred.

As the plasma gas used in the glow discharge treatment, it is possible to use an inorganic gas such as oxygen gas, nitrogen gas, water vapor gas, argon gas, or helium gas, and oxygen gas or a gas mixture of oxygen gas and argon gas is particularly preferred. Specifically, the gas mixture of oxygen gas and argon gas is more desirably used. In a case in which a gas mixture of oxygen gas and argon gas is used, the partial pressure ratio between both gases (oxygen gas and argon gas) is preferably 100:0 to 30:70 and more preferably approximately 90:10 to 70:30. In addition, particularly, a method in which gas is not introduced into a treatment container, and gases such as air entering the treatment container through leaking and water vapor emitted from a substance to be treated are used as the plasma gas is also preferred.

Here, as the pressure of the plasma gas, a low pressure capable of achieving non-equilibrium plasma conditions is required. A specific pressure of the plasma gas is preferably approximately 0.005 Torr to 10 Torr (0.666 to 1,333 Pa) and more preferably in a range of approximately 0.008 Torr to 3 Torr (1.067 to 400 Pa). In a case in which the pressure of the plasma gas is 0.666 Pa or higher, the adhesiveness-improving effect becomes sufficient, and, in a case in which the pressure of the plasma gas is 1,333 Torr or less, discharging becoming unstable due to an increase in an electric current is suppressed.

While it is not possible to determine the specific value of the plasma output since the plasma output varies depending on the shape and size of the treatment container, the shape of the electrode, and the like, the plasma output is preferably approximately 100 W to 2,500 W and more preferably approximately 500 W to 1500 W.

The treatment time of the glow discharge treatment is preferably 0.05 seconds to 100 seconds and more preferably approximately 0.5 seconds to 30 seconds. In a case in which the treatment time is 0.05 seconds or longer, the adhesiveness-improving effect can be sufficiently obtained, and, in a case in which the treatment time is 100 seconds or shorter, it is possible to prevent the deformation, discoloration, and the like of a film to be treated.

The discharge treatment intensity of the glow discharge treatment varies depending on the plasma output and the treatment time, but is preferably in a range of 0.01 kV·A·minutes/m² to 10 kV·A·minutes/m² and more preferably 0.1 kV·A·minutes/m² to 7 kV·A·minutes/m².

In a case in which the discharge treatment intensity is set to 0.01 kV·A·minutes/m² or higher, a sufficient adhesiveness-improving effect can be obtained, and, in a case in which the discharge treatment intensity is set to 10 kV·A·minutes/m² or lower, it is possible to avoid the deformation, discoloration, and the like of the film to be treated.

In the glow discharge treatment, it is also preferable to heat the film to be treated in advance. In such a case, compared with a case in which the film is not heated, favorable adhesiveness can be obtained within a short period of time. The temperature of the heating is preferably in a range of 40° C. to the softening temperature of the film to be treated+20° C. and more preferably in a range of 70° C. to the softening temperature of the film to be treated. In a case in which the temperature of the heating is set to 40° C. or higher, a sufficient adhesiveness-improving effect can be obtained. In addition, in a case in which the temperature of the heating is set to the softening temperature or lower of the film to be treated, it is possible to ensure favorable handling properties of the film during the treatment.

Specific examples of a method for increasing the temperature of the film to be treated in a vacuum include heating using an infrared heater and heating by bringing the film into contact with a hot roll.

Examples of the flame treatment include flame treatments in which flame into which silane compounds are introduced is used.

<Method for Manufacturing White Polyester Film>

The method for manufacturing the stretched white polyester film of the present disclosure is not particularly limited, and the stretched white polyester film of the present disclosure can be preferably manufactured using the following method.

That is, the method for manufacturing the white polyester film of the present disclosure has a non-stretched film formation step of forming a non-stretched film by ejecting a molten substance obtained by melting a mixture including a raw material polyester and white particles from a die and landing the molten substance on a cooling roll, in which a difference between an ejection temperature of the molten substance being ejected from the die and a landing point temperature of the cooling roll is 20° C. or less; a stretching step of forming a biaxial stretched film by stretching the non-stretched film cooled using the cooling roll in a machine direction and a transverse direction; and a heat fixation step of heat-fixing the biaxial stretched film at a temperature of Tm−70° C. or higher and Tm−30° C. or lower in a case in which a melting point of the raw material polyester is represented by Tm° C.

In the method for manufacturing the white polyester film of the present disclosure, a heat relaxation step is preferably carried out after the heat fixation step.

In addition, after the formation of the non-stretched film, before the stretching step, or after stretching in one direction but before stretching in the other direction, inline coating for forming undercoats may also be carried out.

Hereinafter, the respective steps will be specifically described, but the method for manufacturing the white polyester film of the present disclosure is not limited to the following method.

(Non-Stretched Film Formation Step)

In the non-stretched film formation step, a non-stretched film is formed by ejecting a molten substance obtained by melting a mixture including a raw material polyester and white particles from a die and landing the molten substance on a cooling roll. At this time, the difference between the ejection temperature of the molten substance being ejected from the die and the landing point temperature of the cooling roll is set to 20° C. or less.

For example, the above-described raw material including polyester and white particles of titanium oxide or the like is dried and then melted, and the obtained molten substance (melt) is passed through a gear pump and a filter. After that, the molten substance is ejected from a die, extruded onto a cooling roll (cast drum), and cooled and solidified, thereby obtaining a non-stretched film. The raw material is melted using an extruder, and a monoaxial extruder or a multiaxial (biaxial or more) extruder may also be used.

The white particles can be blended into the polyester film using a variety of well-known methods. Typical examples of the method include the following method.

(A) A method in which the white particles are added before the end of an ester exchange reaction or an esterification reaction in the synthesis of the polyester or the white particles are added before the initiation of a polycondensation reaction

(B) A method in which the white particles are added to the polyester and are melted and kneaded

(C) A method in which a master batch (also referred to as a master pellet) to which a large amount of the white particles are added using the method (A) or (B) is manufactured, the master batch and a polyester containing no white particles or a small amount of a white pigment are kneaded together, thereby adding a predetermined amount of the white particles

(D) A method in which the white particles are melted and kneaded using the master pellet in (C)

Among these, the method (C), that is, the method in which a master batch (hereinafter, in some cases, referred to as “MB”) to which a large amount of the white particles are added is manufactured, the master batch and a polyester containing no white particles or a small amount of a white pigment are kneaded together, thereby adding a predetermined amount of the white particles (hereinafter, in some cases, referred to as “master batch method”) is preferred. In addition, it is also possible to employ a method in which a polyester that has not been dried in advance and white particles are injected into an extruder, and a master batch is produced while degassing moisture, the air, and the like. Furthermore, it is preferable to produce a master batch using a polyester that has been dried in advance even to a small extent since an increase in the acid value of the polyester is suppressed. In this case, examples of the method include a method of carrying out extrusion while degassing, a method of carrying out extrusion without degassing using a polyester that has been sufficiently dried.

For example, in the case of producing the master batch (MB), it is preferable to reduce the moisture ratio by drying a polyester resin to be injected in advance. Regarding the drying conditions, the drying temperature is preferably 100° C. to 200° C. and more preferably 120° C. to 180° C., and the drying time is 1 hour or longer, more preferably 3 hours or longer, and still more preferably 6 hours or longer. In this case, the polyester resin is sufficiently dried so that the amount of moisture in the polyester resin preferably reaches 50 ppm or less and more preferably reaches 30 ppm or less.

The method for carrying out preliminary mixing is not particularly limited, and preliminary mixing may be carried out using a method by batch or a monoaxial or multiaxial kneading and extrusion device. In the case of producing the master batch while degassing, it is preferable to employ a method in which a polyester resin is melted at a temperature of 250° C. to 300° C. and preferably 270° C. to 280° C., provide one degassing opening, preferably, two or more degassing openings to a preliminary mixer, carry out continuous suction and degassing at 0.05 MPa or higher and more preferably 0.1 MPa or higher, and maintain the reduced pressure in the mixer.

The extrusion of the molten resin (melt) is preferably carried out under vacuum exhaustion or in an inert gas atmosphere.

The melting temperature in the extruder is preferably the melting point of the raw material polyester being used+80° C. or lower, more preferably the melting point+10° C. or higher and the melting point+70° C. or lower, and still more preferably the melting point+20° C. or higher and the melting point+60° C. or lower. In a case in which the melting temperature in the extruder is the melting point+10° C. or higher, the resin is sufficiently melted, and, on the other hand, in a case in which the melting temperature in the extruder is the melting point+70° C. or lower, the decomposition of the polyester and the like is suppressed, which is preferable. Meanwhile, it is preferable to dry the raw material polyester before the injection of the raw material into the extruder, and the water content is preferably 10 ppm to 300 ppm and more preferably 20 ppm to 150 ppm.

For the purpose of further improving the hydrolysis resistance, in the case of melting the raw material resin, a terminal sealant may be added thereto.

The terminal sealant may be directly added to the extruder at the same time as the polyester and the like, but it is preferable to form and inject the polyester and the master batch into the extruder in advance from the viewpoint of extrusion stability.

The extruded molten substance (melt) is passed through a gear pump, a filter, and a die and is cast onto a cooling roll (cast drum). The shape of the die may be any one of a T die, a hanger coat die, and a fish tail. On the cooling roll, the molten resin (melt) can be adhered to the cooling roll using an electrostatic application method.

The ejection temperature of the molten substance that is ejected from the die is preferably 270° C. to 310° C., more preferably 275° C. to 300° C., and still more preferably 280° C. to 295° C. The ejection temperature from the die can be controlled using the temperature of the molten substance being extruded from the extruder, the temperatures of pipes and the die, and the like.

The surface temperature of the cooling roll can be set to approximately 10° C. to 40° C. The diameter of the cooling roll is preferably 0.5 m or more and 5 m or less and more preferably 1 m or more and 4 m or less. The driving rate (the linear rate of the outermost circumference) of the cooling roll is preferably 1 m/minute or more and 50 m/minute or less and more preferably 3 m/minute or more and 30 m/minute or less.

In the manufacturing of the white polyester film of the present disclosure, in a case in which the molten substance is ejected from the die and landed onto the cooling roll, thereby forming a non-stretched film as described above, the difference (ΔT=T1−T2) between the ejection temperature T1 of the molten substance being ejected from the die and the landing point temperature T2 of the cooling roll is controlled to be 20° C. or less. In a case in which ΔT is set to 20° C. or less, the MD tear strength improves, the cleavage strengths of white polyester films to be manufactured improve, and tan δ also improves, which enables the enhancement of the weather resistance. From such a viewpoint, ΔT is preferably 12° C. or less and more preferably 7° C. or less.

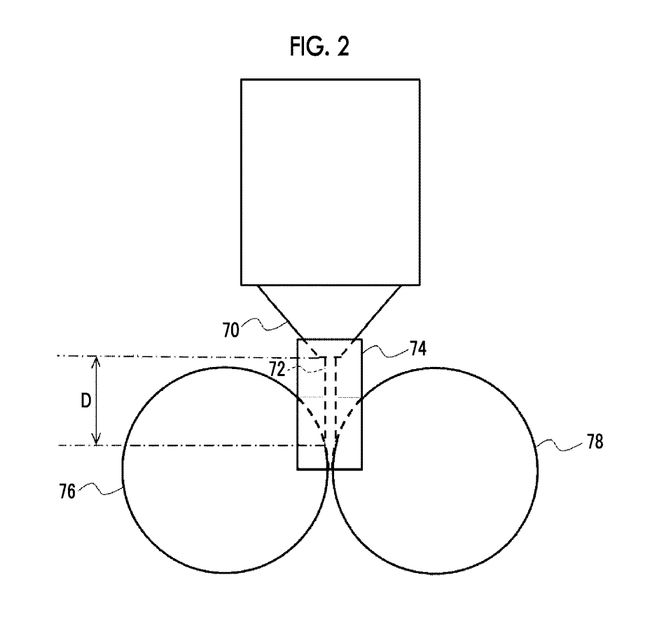

Before landed on the cooling roll, the molten substance ejected from the die is rapidly cooled by means of blasting for cooling a non-stretched film that has been landed on the cooling roll and/or the convection of the external air. Means for suppressing ΔT at 20° C. or less is not particularly limited, and examples thereof include means in which a cover 74 is provided in the vicinity of an ejection portion of a die 70 as illustrated in FIG. 2 and a molten substance 72 extruded from the die 70 is shielded from being hit by the wind. In this case, the cooling rate until the landing of the molten substance 72 ejected from the die 70 on cooling rolls 76 and 78 is alleviated, and ΔT can be suppressed at 20° C. or less. In addition, ΔT can also be suppressed at 20° C. or less by narrowing the gap between the ejection portion of the die 70 and the cooling rolls 76 and 78. For example, ΔT may be suppressed at 20° C. or less by setting the gap D between the ejection portion of the die 70 and the cooling rolls 76 and 78 (the landing points of the molten substance 72) to 10 to 100 mm. In addition, ΔT may be suppressed at 20° C. or less by setting the difference between the set temperature of the ejection portion of the die 70 and the set temperature of the surfaces of the cooling rolls 76 and 78 to be small.

Meanwhile, the ejection temperature T1 of the molten substance 72 being ejected from the die 70 and the landing point temperature T2 of the molten substance 72 being ejected from the die 70 on the cooling rolls 76 and 78 can be respectively measured using a radiation thermometer. The measured view of the radiation thermometer is desirably small, and the measured view is desirably 30 mm or less.

(Stretching Step)

In the stretching step, the non-stretched film cooled on the cooling roll is stretched in the machine direction (MD) and the transverse direction (TD), thereby forming a biaxial stretched film.

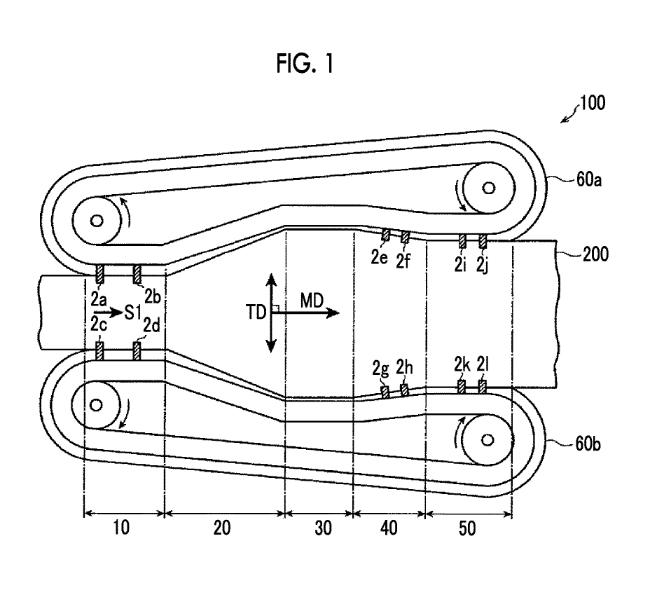

FIG. 1 schematically illustrates an example of a biaxial stretcher that is used to manufacture the stretched white polyester film of the present disclosure. In FIG. 1, a biaxial stretcher 100 and a polyester film 200 mounted in the biaxial stretcher 100 are illustrated. The biaxial stretcher 100 includes a pair of cyclic rails 60a and 60b which are symmetrically arranged with respect to the polyester film 200.

The biaxial stretcher 100 is divided into a preheating portion 10 that preheats the polyester film 200, a stretching portion 20 that stretches the polyester film 200 in an arrow TD direction which is a direction orthogonal to an arrow MD direction so as to impart tension to the polyester film, a heat fixation portion 30 that heats the polyester film imparted with tension while maintaining the imparting of the tension, a heat relaxation portion 40 that heat the heat-fixed polyester film so as to relax the tension of the heat-fixed polyester film, and a cooling portion 50 that cools the polyester film which has passed through the heat relaxation portion.

The cyclic rail 60a includes at least holding members 2a, 2b, 2e, 2f, 2i, and 2j capable of moving along the edge of the cyclic rail 60a, and the cyclic rail 60b includes at least holding members 2c, 2d, 2g, 2h, 2k, and 2l capable of moving along the edge of the cyclic rail 60b. The holding members 2a, 2b, 2e, 2f, 2i, and 2j hold one end portion of the polyester film 200 in the TD direction, and the holding members 2c, 2d, 2g, 2h, 2k, and 2l hold the other end portion of the polyester film 200 in the TD direction. The holding members 2a to 2l are generally referred to as chucks, clips, or the like.

In FIG. 1, the holding members 2a, 2b, 2e, 2f, 2i, and 2j moves counterclockwise along the edge of the cyclic rail 60a, and the holding members 2c, 2d, 2g, 2h, 2k, and 2l moves clockwise along the edge of the cyclic rail 60b.

The holding members 2a to 2d hold the end portion of the polyester film 200 in the preheating portion 10, move along the edge of the cyclic rail 60a or 60b while holding the polyester film, pass through the stretching portion 20 and the heat relaxation portion 40 indicated by the holding members 2e to 2h, and proceed up to the cooling portion 50 indicated by the holding members 2i to 2l. After that, the holding member 2a and 2b and the holding member 2c and 2d release the end portion of the polyester film 200 at the end portion of the cooling portion 50 on the downstream side in the MD direction in the transportation direction order, proceed along the edge of the cyclic rail 60a or 60b, and return to the preheating portion 10.

As a result, the polyester film 200 moves in the arrow MD direction in FIG. 1 and is sequentially transported to the preheating portion 10, the stretching portion 20, the heat fixation portion 30, the heat relaxation portion 40, and the heat relaxation portion 50.

The movement rate of the holding members 2a to 2l becomes the transportation rate of the holding portions of the polyester film 200.

The movement rates of the holding members 2a to 2l can be respectively changed.

Therefore, the biaxial stretcher 100, in the stretching portion 20, enables transverse stretching in which the polyester film 200 is stretched in the TD direction and is also capable of stretching the polyester film 200 in the MD direction by changing the movement rates of the holding members 2a to 2l.

That is, it is also possible to carry out biaxial stretching at the same time using the biaxial stretcher 100.

In FIG. 1, only 12 holding members 2a to 2l that hold the end portion of the polyester film 200 in the TD direction are illustrated; however, in order to support the polyester film 200, the biaxial stretcher 100 may have holding members not illustrated in the drawing in addition to 2a to 2l.

Meanwhile, hereinafter, the holding members 2a to 2l will also be collectively referred to as “holding member 2”.

(Preheating Portion)

In the preheating portion 10, the polyester film 200 is preheated. The transverse stretching of the polyester film 200 is facilitated by heating the polyester film 200 in advance before stretching.

The film surface temperature at the end point of the preheating portion (hereinafter, also referred to as “preheating temperature”) is, in a case in which the glass transition temperature of the polyester film 200 is represented by Tg, preferably Tg−10° C. to Tg+60° C. and more preferably Tg° C. to Tg+50° C.

Meanwhile, the end point of the preheating portion refers to a point in time at which the preheating of the polyester film 200 ends, that is, a location at which the polyester film 200 is released from the region of the preheating portion 10.

(Stretching Portion)

In the stretching portion 20, the preheated polyester film 200 is transverse-stretched at least in a direction (TD) orthogonal to the machine direction (transportation direction, MD) of the polyester film 200, thereby imparting tension to the polyester film 200.

The stretching (transverse stretching) of the polyester film 200 in the direction (TD) orthogonal to the machine direction (transportation direction, MD) refers to stretching in a direction at a perpendicular (90°) angle with respect to the machine direction (transportation direction, MD) of the polyester film 200.

Machine Stretching

In biaxial stretching, the non-stretched film formed in the non-stretched film formation step is machine-stretched in the machine direction of the polyester film, for example, at a stretching stress of 5 MPa or more and 15 MPa or less and a stretch ratio of 2.5 times or more and 4.5 times or less.

More specifically, the polyester film is guided to a roll group heated to a temperature of 70° C. or higher and 120° C. or lower and is machine-stretched in the machine direction (transportation direction, MD) at a stretching stress of 5 MPa or more and 15 MPa or less and a stretch ratio of 2.5 times or more and 4.5 times or less and more preferably at a stretching stress of 8 MPa or more and 14 MPa or less and a stretch ratio of 3.0 times or more and 4.0 times or less. After the machine stretching, the polyester film is preferably cooled in the roll group having a temperature of 20° C. or higher and 50° C. or lower.

Transverse Stretching

After the machine stretching, transverse stretching is carried out. The transverse stretching is preferably carried out using a tenter. The machine-stretched white polyester film is guided to a tenter and is stretched in the transverse direction (TD stretching) in an atmosphere heated to, for example, a temperature of 80° C. or higher and 180° C. or lower (stretching temperature). In the tenter, both ends of the polyester film are held using clips, and the clips are broadened in a direction perpendicular to the machine direction, that is, the transverse direction while transporting the polyester film to a thermal treatment zone, whereby transverse stretching can be carried out.

In the transverse stretching, the polyester film formed is preferably transverse-stretched at a stretching stress of 8 MPa or more and 20 MPa or less and a stretch ratio of 3.4 times or more and 5 times or less and more preferably transverse-stretched at a stretching stress of 10 MPa or more and 18 MPa or less and a stretch ratio of 3.6 times or more and 4.5 times or less.

The stretched area ratio (machine stretch ratio×transverse stretch ratio) by the biaxial stretching is preferably 9 times or more and 20 times or less. In a case in which the area ratio is 9 times or more and 20 times or less, biaxially-oriented polyester films having, for example, a thickness after the stretching of 250 μm or more and 500 μm or less, a high degree of orientation, a degree of crystallization of 30% or more and 40% or less, an equilibrium moisture content of 0.1% by mass or more and 0.25% by mass or less can be obtained.

The method for the biaxial stretching may be any one of a sequential biaxial stretching method in which stretching is separately carried out in the machine direction and the transverse direction as described above and a simultaneous biaxial stretching method in which stretching is carried out at the same time in the machine direction and the transverse direction.

(Heat Fixation Step)

In the heat fixation step, with respect to the melting point Tm° C. of the raw material polyester, the biaxial stretched film is heat-fixed at a temperature of Tm−70° C. or higher and Tm−30° C. or lower. For example, in a case in which the melting point of PET that is used as the raw material is 257° C., the heat fixation is carried out at 187° C. to 227° C.

Meanwhile, the heat fixation temperature mentioned herein refers to the peak surface temperature of the film during a heat fixation treatment and can be measured using a radiation thermometer.

In a case in which the biaxial stretched film is heat-fixed at a temperature of (Tm−70)° C. to (Tm−30)° C., it is possible to control the crystal and tensioned amorphous state of the biaxial stretched film.

In a case in which the heat fixation temperature is (Tm−70)° C. or higher with respect to the melting point Tm° C. of the raw material polyester, the tan δ peak temperature does not become too high, the TD tear strength can be improved, and the cleavage strength can be improved. On the other hand, in a case in which the heat fixation temperature is (Tm−30)° C. or lower with respect to the melting point Tm° C. of the raw material polyester, the tan δ peak temperature does not become too low, the weather resistance can be improved.

The heat fixation is preferably carried out subsequent to the transverse stretching in a state of holding the polyester film with the chucks in the tenter, and, in this case, the interval between the chucks may be equal to or wider or narrower than the width thereof at the end of the transverse stretching. In a case in which the heat fixation treatment is carried out, fine crystals are generated, and it is possible to improve dynamic characteristics and durability.

Regarding the time of the heat fixation, the thermal treatment is carried out on the film for preferably 1 second to 60 seconds and more preferably 5 seconds to 50 seconds.

In the heat fixation step provided after the stretching step, some of volatile basic compounds having a boiling point of 200° C. or lower may be volatilized.

(Heat Relaxation Step)

Subsequent to the heat fixation step, a heat relaxation step is preferably carried out. The heat relaxation step refers to a treatment of contracting the film by heating the film in order to relax stress. In the heat relaxation step, the film is preferably relaxed in at least one direction of the machine direction and the transverse direction, and the relaxation amount is preferably 1% to 30% (a ratio to the width after the transverse stretching), more preferably 2% to 20%, and still more preferably 3% to 15% in both the machine direction and the transverse direction. In a case in which the heat relaxation temperature is represented by Tr and the heat fixation temperature is represented by Ts, the heat relaxation temperature Tr is preferably in a range of 100° C. or higher and Ts−15° C. or more (100° C.≦Tr≦Ts−15° C.), more preferably in a range of 110° C. or higher and Ts−25° C. or more (110° C.≦Tr≦Ts−25° C.), and particularly preferably in a range of 120° C. or higher and Ts−30° C. or more (120° C.≦Tr≦Ts−30° C.).

In the heat relaxation step, the polyester film is heat-relaxed under the conditions of the above-described ranges, and the tension of the polyester film is somewhat relaxed, whereby the dimensional stability becomes favorable while maintaining the hydrolysis resistance, and malfunction does not easily occur in subsequent steps such as the processing of the obtained polyester film.

Transverse relaxation can be carried out by contracting the interval between the facing clips (the interval between the cyclic rails 60a and 60b) in the tenter. In addition, machine relaxation can be carried out by narrowing the interval between the clips adjacent to each other in the tenter. This can be achieved by coupling the adjacent clips in a pantagraph shape and contracting this pentagraph. In addition, it is also possible to remove the film from the tenter and then thermally treat the film while being transported at a low tension, thereby relaxing the film. The tension per cross-sectional area of the film is preferably 0 N/mm² to 0.8 N/mm², more preferably 0 N/mm² to 0.6 N/mm², and still more preferably 0 N/mm² to 0.4 N/mm². The heat relaxation can be carried out at 0 N/mm² by providing two or more nip rolls in the case of transporting the film and loosening the film between the nip rolls (in a dangling shape).

(Winding Step)

Both ends of the film removed from the tenter, which have been held by the clips, are trimmed, knurled (embossed), and then wound in a roll shape, thereby obtaining a film roll.

The width of the wound film is preferably 0.8 m to 10 m, more preferably 1 m to 6 m, and still more preferably 1.2 m to 4 m. The thickness is preferably 30 μm to 500 μm, more preferably 40 μm to 480 μm, and still more preferably 45 μm to 450 μm. The thickness can be adjusted by adjusting the ejection amount from the die in the extruder and adjusting the film formation rate (adjusting the rate of the cooling roll and the stretching rate and the like varying in association with the rate of the cooling roll).

Meanwhile, the film for recycling such as the edge portion of the trimmed film is collected and recycled as a resin mixture. The film for recycling is used as a film raw material of the next lot of white polyester films and is returned to a drying step as described above, and the manufacturing steps are sequentially repeated.

Through the above-described steps, the white polyester film of the present disclosure can be manufactured.

<Solar Cell Back Sheet>

A solar cell back sheet of the present disclosure includes the white polyester film of the present disclosure.

In the solar cell back sheet of the present disclosure, functional layers can be provided on at least one surface of the white polyester film of the present disclosure as necessary. Examples thereof include an easy adhesive layer that enhances the adhesive force to adherends, an ultraviolet-absorbing layer, a weather-resistant layer, and the like.

The solar cell back sheet of the present disclosure includes the white polyester film of the present disclosure and thus exhibits stable weather resistance, adhesiveness, and light reflectivity for a long period of use.

As the method for providing the functional layers on at least one surface of the white polyester film of the present disclosure, it is possible to use well-known techniques such as a roll coating method, a knife edge coating method, a gravure coating method, and a curtain coating method. In addition, the functional layers may be formed by means of the above-described inline coating.

In a case in which the solar cell back sheet has a functional layer (coated layer) formed by means of coating on at least one surface of the stretched white polyester film of the present disclosure, it is possible to further improve any of weather resistance, light reflectivity, and adhesiveness or impart other functions.

In addition, before the provision of the coating layer by means of coating, a surface treatment (a flame treatment, a corona treatment, a plasma treatment, an ultraviolet treatment, or the like) may be carried out.

In addition, it is also preferable to attach other functional films to the white polyester film of the present disclosure through as adhesive layer.

<Solar Cell Module>

A solar cell module of the present disclosure includes a solar cell element, a sealing material that seals the solar cell element, a front substrate disposed on the outside of the sealing material on a light-receiving surface side of the solar cell element, and the solar cell back sheet according to the above-described embodiment disposed on the outside of the sealing material on a side opposite to the light-receiving surface side of the solar cell element.

That is, the solar cell module of the present disclosure is constituted by disposing a solar cell element that converts the light energy of sunlight to an electric energy between a transparent front substrate (front surface protection member) on which the sunlight is incident and the solar cell back sheet of the present disclosure described above (rear surface protection member) and sealing the solar cell element disposed between the front substrate and the back sheet with a sealing material such as ethylene vinyl acetate (EVA). The solar cell module includes the solar cell back sheet including the white polyester film of the present disclosure, whereby the occurrence of peeling and cracking caused by the hydrolysis of the solar cell back sheet is suppressed, and the power generation efficiency can be enhanced by reflecting light rays in the visible light range and the infrared range toward the solar cell element at a high reflectivity. Therefore, the solar cell module of the present disclosure is capable of maintaining a high power generation efficiency outdoors for a long period of time.

Regarding members other than the solar cell module and the back sheet, for example, “The Constituent Materials of Photovoltaic Power Generation Systems” (edited by Eiichi Sugimoto and published by Kogyo Chosakai Publishing Co., Ltd. in 2008) describes the members in detail.

The transparent front substrate needs to have a light-transmitting property so as to be capable of transmitting sunlight and can be appropriately selected from base materials transmitting light. From the viewpoint of power generation efficiency, the light transmittance of the substrate is preferably higher, and, as the above-described substrate, for example, a glass substrate, a substrate of a transparent resin such as an acrylic resin, or the like can be preferably used.

As the solar cell element, it is possible to apply a variety of well-known solar cell elements such as a solar cell element based on silicon such as monocrystalline silicon, polycrystalline silicon, or amorphous silicon or a solar cell element based on a III-V group or II-VI group compound semiconductor such as copper-indium-gallium-selenium, copper-indium-selenium, cadmium-tellurium, or gallium-arsenic.

The white polyester film of the present disclosure is preferable as a base material film of the solar cell back sheet, but the applications of the white polyester film of the present disclosure is not limited to solar cell back sheets, and can be used as films that are used outdoors for a long period of time. Specific examples thereof include construction films, outdoor advertisement films, heat barrier films, and the like as well as solar cell protective films.

### EXAMPLES

Hereinafter, the present disclosure will be more specifically described using examples, but the present disclosure is not limited to the following examples within the scope of the gist of the present invention. Meanwhile, unless particularly otherwise described, “parts” is on the basis of mass.

### Example 1

<Synthesis of Raw Material Polyester Resin 1>

As described below, terephthalic acid and ethylene glycol were directly reacted with each other so as to distill water away and were esterified, and a polyester resin (Ti catalyst-based PET) was obtained using a direct esterification method in which polycondensation was carried out at a reduced pressure and a continuous polymerization device.

(1) Esterification Reaction

In a first esterification reaction tank, highly pure terephthalic acid (4.7 ton) and ethylene glycol (1.8 ton) were mixed together for 90 minutes so as to form a slurry, and the slurry was continuously supplied to the first esterification reaction tank at a flow rate of 3,800 kg/h. Furthermore, an ethylene glycol solution of a citric acid chelate titanium complex (VERTEC AC-420, manufactured by Johnson Matthey) in which citric acid coordinated Ti metal was continuously supplied, and a reaction was caused under stirring at an inner temperature of the reaction tank of 250° C. for an average residence time of approximately 4.3 hours. At this time, the citric acid chelate titanium complex was continuously added so that the amount of Ti added reached 9 ppm in terms of the element equivalent value. The acid value of the obtained oligomer was 600 equivalents/ton.

The obtained reaction product (oligomer) was transferred to a second esterification reaction tank and was reacted under stirring at an inner temperature of the reaction tank of 250° C. for an average residence time of 1.2 hours, thereby obtaining an oligomer having an acid value of 200 equivalents/ton. The inside of the second esterification reaction tank was divided into three zones, an ethylene glycol solution of magnesium acetate was continuously supplied from a second zone so that the amount of Mg added reached 75 ppm in terms of the element equivalent value, and subsequently, an ethylene glycol solution of trimethyl phosphate was continuously supplied from a third zone so that the amount of P added reached 65 ppm in terms of the element equivalent value.

(2) Polycondensation Reaction

The esterification reaction product obtained above was continuously supplied to a first polycondensation reaction tank and was polycondensed under stirring at a reaction temperature of 270° C. and an inner pressure of the reaction tank of 20 torr (2.67×10⁻³ MPa) for an average residence time of approximately 1.8 hours.

The reaction product that had passed through the first polycondensation reaction tank was further transferred to a second polycondensation reaction tank and was reacted (polycondensed) in this reaction tank under stirring at an inner temperature of the reaction tank of 276° C. and an inner pressure of the reaction tank of 5 torr (6.67×10⁻⁴ MPa) for an average residence time of approximately 1.2 hours.

Next, the reaction product that had passed through the second polycondensation reaction tank was further transferred to a third polycondensation reaction tank and was reacted (polycondensed) in this reaction tank under conditions of an inner temperature of the reaction tank of 278° C., an inner pressure of the reaction tank of 1.5 torr (2.0×10⁻⁴ MPa), and an average residence time of 1.5 hours, thereby obtaining polyethylene terephthalate (PET). On the obtained PET (reaction product), measurement was carried out using a high resolution inductively coupled plasma mass spectrometry (HR-ICP-MS; AttoM manufactured by Seiko Instruments Inc.). As a result, Ti=9 ppm, Mg=67 ppm, and P=58 ppm. P was slightly reduced with respect to the original amount added and was assumed to have been volatilized in the polymerization process.

Solid Phase Polymerization

A pellet (diameter: 3 mm, length: 7 mm) was produced from PET polymerized above, and solid phase polymerization was carried out on the obtained resin pellet (intrinsic viscosity IV=0.60 dL/g, concentration of terminal carboxyl groups=16 equivalents/ton) as described below.

In the solid phase polymerization, the polyester polymerized by the above-described esterification reaction was heated using nitrogen (the dew-point temperature−30° C.) at 140° C. for seven minutes, and preliminary crystallization was carried out for the purpose of preventing fixation during the solid phase polymerization.

Next, the polyester was dried at 180° C. for seven hours using heated nitrogen (the dew-point temperature−30° C.), and the moisture ratio in the resin was set to 50 ppm or less.

Next, the dried polyester resin was preliminarily heated at 210° C., and then nitrogen was circulated at 195° C. for 50 hours, thereby causing the solid phase polymerization to proceed. As the nitrogen circulation conditions, the gas ratio (the amount of nitrogen gas being circulated to the amount of the resin being discharged) was set to 1.3 m³/kg, the superficial velocity was set to 0.08 m/second, the concentration of ethylene glycol was set to 240 ppm, the concentration of water was set to 12 ppm, and nitrogen having a molar partial pressure ratio of ethylene glycol to water (the molar partial pressure of ethylene glycol/the molar partial pressure of water) of 20 was used, thereby causing the solid phase polymerization to proceed. In order to obtain the above-described gas mixture composition, highly pure ethylene glycol having a water content of 100 ppm was used as the ethylene glycol scrubber, and the temperature of the scrubber was set to 35° C. The pressure in the scrubber was set in a range of 0.1 MPa to 0.11 MPa.

Next, the resin (750 kg/h) discharged from the reaction step was cooled to 60° C.

The obtained polyester resin after the solid phase polymerization had an intrinsic viscosity (IV) of 0.78 dL/g, an amount of terminal COOH (AV) of 9 equivalents/ton, and a melting point (Tm) of 257° C.

<Production of Master Pellet>

Titanium oxide was added to and kneaded with a part of the pellet before the solid phase polymerization so that the content ratio thereof reached 50% by mass of the entire pellet, thereby producing a master pellet (master batch).

Here, as the titanium oxide, titanium oxide manufactured by Ishihara Sangyo Kaisha, Ltd. (trade name: PF-739; average primary particle diameter: 0.25 μm) was used.

<Formation of Non-Stretched Film>

PET-1 that had been fully solid-phase-polymerized as described above and the master pellet were dried so that the water contents reached 100 ppm or less respectively, mixed together so that the amount of the titanium oxide reached 4% by mass, injected into a hopper of a kneading and extrusion device, melted at 290° C., and extruded. Meanwhile, as the extruder, a double vent-type identical direction rotary engagement-type biaxial extruder (diameter: 110 mm) including vents at two places was used. This molten substance (melt) was passed through a gear pump and a filter (pore diameter: 20 μm) and then extruded from a die to a cooling cast drum (cooling roll). Meanwhile, the extruded melt was adhered to the cooling cast drum (cooling roll) using an electrostatic application method.

The interval between an ejection portion of the die and the cooling roll was set to 40 mm, a portion from the ejection portion of the die to the landing point on the cast drum (cooling roll) was covered with a heat-resistant wind-shield cover, and attention was paid to prevent the wind from hitting the molten substance ejected from the die before landing on the cast drum.

In addition, the ejection temperature T1 of the molten substance and the landing point temperature T2 of the cooling roll were respectively measured as described below using a radiation thermometer (manufactured by Horiba Ltd. IT-545S).

Ejection Temperature T1 of Molten Substance:

The ejection temperature T1 of the molten substance (melt) is measured at a place closest to the die ejection portion while the measured view of the radiation thermometer is adhered to the cast drum from the die ejection portion. At this time, the ejection temperature generally becomes the peak temperature of melt temperatures that can be measured with the radiation thermometer.

Landing Point Temperature T2 of Cooling Roll:

The landing point temperature T2 of the cooling roll is measured at a place closest to the adhesion initiation point in a base portion (non-stretched film) after the measured view of the radiation thermometer is adhered to the cast drum.

As a result, a non-stretched polyethylene terephthalate (PET) film having a thickness of approximately 3 mm was formed.

<Stretching of Non-Stretched Film>

Machine Stretching

The non-stretched film was passed through between two pairs of nip rolls having different circumferential velocities and stretched in the machine direction (transportation direction) under the following conditions.

Preheating temperature: 75° C.

Stretching temperature: 92° C.

Stretch ratio: 3.0 times

Stretching rate: 300%/second

Transverse Stretching

After the machine stretching, transverse stretching was carried out. The transverse stretching was carried out under the following conditions in a tenter.

Preheating temperature: 110° C.

Stretching temperature: 150° C.

Stretch ratio: 4.2 times

Stretching rate: 15%/second

Heat Fixation

The biaxial stretched film that had been fully machine-stretched and transverse-stretched was heat-fixed at 190° C. (heat fixation time: 7 seconds).

Heat Relaxation

After the heat fixation, heat relaxation was carried out by contracting the tenter width (heat relaxation temperature: 160° C.).

Winding

After the heat fixation and the heat relaxation, both ends were respectively trimmed 10 cm. After that, both ends were embossed (knurled) in a width of 10 mm, and then the film was wound at a tension of 25 kg/m. The film width was 1.5 m, and the winding length was 2,000 m.

In the above-described manner, a biaxial stretched white polyester film (thickness: 250 μm) of Example 1 was obtained.

### Examples 2 to 13 and Comparative Examples 1 to 7

Biaxial stretched white polyester films of Examples 2 to 13 and Comparative Examples 1 to 7 were manufactured in the same manner as in Example 1 except for the fact that the manufacturing conditions (ΔT and the heat fixation temperature) and film properties were changed as shown in Table 1.

Meanwhile, ΔT was adjusted by changing the location and range of the wind-shield cover and the interval between the ejection portion in the die and the cooling roll.

[Evaluations of Films]

On the biaxial stretched white polyester films obtained in the examples and the comparative examples, the following evaluations were carried out. The measurement results and the evaluation results of the respective films are shown in Table 1.

<Concentration of Terminal Carboxyl Groups>

0.1 g of a specimen obtained by cutting the film was dissolved in 10 mL of benzyl alcohol, then, a phenol red indicator was added dropwise to a solution mixture to which chloroform was added, and this solution was titrated with a reference liquid (0.01 mol/L KOH-benzyl alcohol solution mixture). The concentration of the terminal carboxyl groups [equivalents/ton] was computed from the titration amount.

<Thickness>

The thickness of the film is the average thickness of the film measured using a contact-type film thickness measurement instrument (manufactured by Mitutoyo Corporation, ID-F125). Specifically, using the contact-type film thickness measurement instrument, 50 points are sampled at equal intervals in a length of 0.5 m in the longitudinal direction of the polyester film, 50 points are sampled at equal intervals (points that evenly divide the film in the width direction into 50 parts) throughout the entire width of the formed film in the width direction, and the thicknesses at these 100 points are measured. The average value of the obtained thicknesses at the 100 points is obtained and considered as the thickness of the polyester film.

<Intrinsic Viscosity>

The manufactured polyester film was dissolved in a 1,1,2,2-tetrachloroethane/phenol (=2/3 [mass ratio]) solvent mixture, and the intrinsic viscosity (IV; unit: dL/g) was obtained from the solution viscosity at 25° C. in the solvent mixture.

ηsp/C=[η]+K[η]2·C

Here, ηsp=(solution viscosity/solvent viscosity)−1, C represents the mass of the polymer dissolved in 100 mL of the solvent (set to 1 g/100 mL in the present measurement), and K represents the Huggis constant (set to 0.343). The solution viscosity and the solvent viscosity were respectively measured using an Ostwald viscometer.

<tan δ Peak Temperature>

After the humidity was adjusted at 25° C. and a relative humidity of 60% for two or more hours, the tan δ peak temperature of the manufactured polyester film was measured using a commercially available dynamic viscoelasticity measurement instrument (VIBRON DVA-225 manufactured by IT Keisoku Seigyo Corporation, Osaka, Japan) under conditions of a temperature-increase rate of 2° C./minute, a measurement temperature range of 30° C. to 200° C., and a frequency of 1 Hz.

<Tear Strength>

The tear strengths of the polyester films obtained in the respective examples were measured as described below.

A 2 cm-wide (short side)×10 cm-long (long side) sample film is cut out in the MD and TD directions respectively.

A 5 cm-long notch is provided parallel to the long side direction at the center of the short side, and the stress is measured using a tensile tester and the following method. The stress is measured at 25° C. and a relative humidity of 50%.

(1-1) One end of the notched portion is held at one chuck of the tensile tester, and the other end is held at the other chuck.

(1-2) The chucks are pulled at 30 mm/minute, and the tensile stress is measured. As the distance between the chucks increases, the stress increases, and a flat portion appears. The stress in the flat portion is considered as the tear strength, the tear strength is measured three times (n=3), and the average value thereof is obtained.

(1-3) This measurement is carried out in MD and TD respectively, and the average values are considered as the tear strengths in the respective directions.

<EVA Adhesiveness>

The polyester film obtained in each of the examples was cut to 20 mm-wide×150 mm-long, thereby preparing two sample pieces. An EVA sheet (EVA sheet: SC50B manufactured by Mitsui Chemicals, Inc.) cut to be 20 mm wide and 100 mm long was sandwiched between these two sample pieces and hot-pressed using a vacuum laminator manufactured by Nisshinbo Mechatronics Inc., thereby being adhered to the EVA sheet. The adhesion conditions at this time were as described below.

After vacuuming at 128° C. for three minutes using the vacuum laminator, the polyester film and the EVA sheet were pressurized for two minutes and thus temporarily adhered to each other. After that, a principal adhesion treatment was carried out in a dry oven at 150° C. for 30 minutes. In this manner, a specimen for adhesiveness evaluation in which a 20 mm portion from one end of the two sample pieces adhered to each other was not adhered to EVA and the remaining 100 mm portion was adhered to the EVA sheet was obtained.

The EVA non-adhered portion of the obtained specimen for adhesiveness evaluation was sandwiched between upper and lower clips in a tensilon (RTC-1210A manufactured by ORIENTEC Co., Ltd.), a tensile test was carried out at a peeling angle of 180° and a tensile rate of 300 mm/minute, and the adhesive force was measured.

Rankings were given on the basis of the average values obtained from the EVA adhesive forces measured in MD and TD according to the following evaluation standards. Among these, Rankings A and B are in a practically permissible range.

<Evaluation Standards>

A: 5.5 N/mm or more

B: 5.0 N/mm or more and less than 5.5 N/mm

C: Less than 5.0 N/mm

<Weather Resistance (Hydrolysis Resistance)>

On the obtained films, a treatment was carried out for a predetermined time under heat and humidity conditions of 120° C. and 100%, and then, the fracture elongations were measured using JIS-K7127 method (1999) and evaluated according to the following evaluation standards. Among these, Rankings A and B are in a practically permissible range.

A: The time taken for the fracture elongation to decrease to 50% of the non-stretched film is longer than 105 hours

B: The time taken for the fracture elongation to decrease to 50% of the non-stretched film is longer than 90 hours and 105 hours or shorter

C: The time taken for the fracture elongation to decrease to 50% of the non-stretched film is 90 hours or shorter

Table 1 shows the properties of the films, manufacturing conditions, and evaluations.

TABLE 1

| | | | | | | | Manufacturing conditions | | | | Evaluation results | | | |
|---|---|---|---|---|---|---|---|---|---|---|---|---|---|---|
| | Properties of films | | | | | | | Landing | | | | | Weather | |
| | MD tear | TD tear | | | | | | point | | | | | resistance | |
| | strength F_{MD} | strength F_{TD} | MD tear | | | | | temperature | | | | | (time taken | |
| | (at equivalent | (at equivalent | strength | Concentration | | Intrinsic | Ejection | T2 of | | Heat | | | for fracture | |
| | of thickness | of thickness | F_{MD}/TD tear | of terminal | tan δ peak | viscosity | temperature | cooling | ΔT | fixation | | | elongation to | |
| | of 250 μm) | of 250 μm) | strength F_{TD} | COOH | temperature | IV | T1 | roll | (=T1 − T2) | temperature | EVA adhesiveness | | halve) | |
| | N | N | — | groups AV | ° C. | dL/g | ° C. | ° C. | ° C. | ° C. | N/mm | | h | |
| Example 1 | 3.3 | 2.4 | 1.38 | 24 | 135 | 0.75 | 295 | 275 | 20 | 190 | 5.0 (MD, TD = 5.1 4.9) | B | 123 | A |
| Example 2 | 3.6 | 3.3 | 1.09 | 24 | 130 | 0.75 | 295 | 275 | 20 | 200 | 5.3 (MD, TD = 5.2 5.4) | B | 112 | A |
| Example 3 | 4.8 | 2.4 | 2.00 | 24 | 136 | 0.75 | 295 | 283 | 12 | 190 | 5.4 (MD, TD = 6.0 4.8) | B | 125 | A |
| Example 4 | 5.1 | 3.3 | 1.55 | 24 | 131 | 0.75 | 295 | 283 | 12 | 200 | 5.8 (MD, TD = 6.2 5.4) | A | 114 | A |
| Example 5 | 5.4 | 4.2 | 1.29 | 24 | 125 | 0.75 | 295 | 283 | 12 | 210 | 6.2 (MD, TD = 6.3 6.0) | A | 103 | B |
| Example 6 | 5.6 | 4.8 | 1.17 | 24 | 120 | 0.75 | 295 | 283 | 12 | 220 | 6.4 (MD, TD = 6.5 6.3) | A | 92 | B |
| Example 7 | 5.3 | 2.4 | 2.21 | 24 | 137 | 0.75 | 295 | 288 | 7 | 190 | 5.2 (MD, TD = 5.6 4.8) | B | 126 | A |
| Example 8 | 5.6 | 3.3 | 1.70 | 24 | 131 | 0.75 | 295 | 288 | 7 | 200 | 5.6 (MD, TD = 5.8 5.4) | A | 115 | A |
| Example 9 | 5.8 | 4.2 | 1.38 | 24 | 126 | 0.75 | 295 | 288 | 7 | 210 | 5.9 (MD, TD = 5.8 6.0) | A | 104 | B |
| Example 10 | 6.0 | 4.8 | 1.25 | 24 | 120 | 0.75 | 295 | 288 | 7 | 220 | 6.1 (MD, TD = 5.9 6.3) | A | 93 | B |
| Example 11 | 5.1 | 3.3 | 1.55 | 15 | 131 | 0.75 | 295 | 283 | 12 | 200 | 5.8 (MD, TD = 6.2 5.4) | A | 140 | A |
| Example 12 | 5.1 | 3.3 | 1.55 | 24 | 131 | 0.63 | 295 | 283 | 12 | 200 | 5.8 (MD, TD = 6.2 5.4) | A | 105 | B |
| Example 13 | 5.1 | 3.3 | 1.55 | 24 | 131 | 0.85 | 295 | 283 | 12 | 200 | 5.8 (MD, TD = 6.2 5.4) | A | 120 | A |
| Comparative | 1.7 | 2.4 | 0.71 | 24 | 134 | 0.75 | 295 | 265 | 30 | 190 | 4.5 (MD, TD = 4.2 4.8) | C | 121 | A |
| Example 1 | | | | | | | | | | | | | | |
| Comparative | 2.7 | 4.8 | 0.56 | 24 | 118 | 0.75 | 295 | 265 | 30 | 220 | 5.4 (MD, TD = 4.6 6.2) | B | 88 | C |
| Example 2 | | | | | | | | | | | | | | |
| Comparative | 2.8 | 1.0 | 2.80 | 24 | 140 | 0.75 | 295 | 275 | 20 | 180 | 4.2 (MD, TD = 4.6 3.8) | C | 132 | A |
| Example 3 | | | | | | | | | | | | | | |
| Comparative | 4.3 | 5.4 | 0.80 | 24 | 113 | 0.75 | 295 | 275 | 20 | 230 | 6.2 (MD, TD = 5.6 6.7) | A | 79 | C |
| Example 4 | | | | | | | | | | | | | | |
| Comparative | 4.8 | 1.0 | 4.80 | 24 | 141 | 0.75 | 295 | 288 | 7 | 180 | 4.6 (MD, TD = 5.4 3.8) | C | 135 | A |
| Example 5 | | | | | | | | | | | | | | |
| Comparative | 6.2 | 5.7 | 1.09 | 24 | 109 | 0.75 | 295 | 288 | 7 | 240 | 6.4 (MD, TD = 6.0 6.7) | A | 82 | C |
| Example 6 | | | | | | | | | | | | | | |
| Comparative | 5.1 | 3.3 | 1.55 | 30 | 131 | 0.75 | 295 | 283 | 12 | 200 | 5.8 (MD, TD = 6.2 5.4) | A | 88 | C |
| Example 7 | | | | | | | | | | | | | | |

As shown in Table 1, it is found that the white polyester films of the examples are all ranked at A or B in the evaluations of weather resistance and adhesiveness and have weather resistance and adhesiveness. Particularly, in a case in which the TD tear strength F_{TD} at an equivalent of a thickness of 250 μm is 2 to 4 N, the white polyester films are excellent in terms of weather resistance and, particularly, weather resistance and adhesiveness.

The disclosure of Japanese Patent Application No. 2015-074615 filed on Mar. 31, 2015 is all incorporated into the present specification by reference.

All of publications, patents, patent applications, and technical standards described in the present specification are incorporated into the present specification by reference as much as a case in which the respective publications, patents, patent applications, and technical standards are specifically and respectively incorporated by reference.

What is claimed is:

1. A white polyester film comprising:
a polyester; and white particles,
wherein, at an equivalent of a thickness of 250 μm, a machine stretching direction tear strength F_{MD} is 2.5 to 6.0 N, a transverse stretching direction tear strength F_{TD} is 2.0 to 5.0 N, and a ratio of the machine stretching direction tear strength F_{MD} to the transverse stretching direction tear strength F_{TD} is 1.05 to 4.00, and
a concentration of terminal carboxyl groups is 5 to 25 equivalents/ton.

2. The white polyester film according to claim 1,
wherein a peak temperature of tan δ measured using a dynamic viscoelasticity measurement instrument is 122° C. to 133° C.

3. The white polyester film according to claim 1,
wherein a content of the white particles is 2% to 10% by mass with respect to a total mass of the film.

4. The white polyester film according to claim 1,
wherein an intrinsic viscosity is 0.65 to 0.90 dL/g.

5. The white polyester film according to claim 1,
wherein, at an equivalent of a thickness of 250 μm, the transverse stretching direction tear strength F_{TD} is 2.0 to 4.0 N.

6. The white polyester film according to claim 1,
wherein the white polyester film is a film roll wound in a roll shape.

7. The white polyester film according to claim 1, wherein:
the polyester is polyethylene terephthalate;
the white particles are titanium dioxide particles;
at an equivalent of a thickness of 250 μm, a machine stretching direction tear strength F_{MD} is 3.3 to 6.0 N, a transverse stretching direction tear strength F_{TD} is 2.4 to 4.8 N, and a ratio of the machine stretching direction tear strength F_{MD} to the transverse stretching direction tear strength F_{TD} is 1.09 to 2.21;
a concentration of terminal carboxyl groups is 15 to 24 equivalents/ton;
a peak temperature of tan δ measured using a dynamic viscoelasticity measurement instrument is 120° C. to 137° C.;
a content of the white particles is 3% to 6% by mass with respect to a total mass of the film;
an intrinsic viscosity is 0.63 to 0.85 dL/g; and
a thickness is 250 μm.

8. A method for manufacturing the white polyester film according to claim 1, comprising:
a non-stretched film formation step of forming a non-stretched film by ejecting a molten substance obtained by melting a mixture including a raw material polyester and white particles from a die and landing the molten substance on a cooling roll, in which a difference between an ejection temperature of the molten substance being ejected from the die and a landing point temperature of the cooling roll is 20° C. or less;
a stretching step of forming a biaxial stretched film by stretching the non-stretched film cooled using the cooling roll in a machine direction and a transverse direction; and
a heat fixation step of heat-fixing the biaxial stretched film at a temperature of Tm−70° C. or higher and Tm−30° C. or lower in a case in which a melting point of the raw material polyester is represented by Tm° C.

9. A solar cell back sheet comprising:
the white polyester film according to claim 1.

10. The solar cell back sheet according to claim 9,
wherein, in the white polyester film, a peak temperature of tan δ measured using a dynamic viscoelasticity measurement instrument is 122° C. to 133° C.

11. The solar cell back sheet according to claim 9,
wherein, in the white polyester film, a content of the white particles is 2% to 10% by mass with respect to a total mass of the film.

12. The solar cell back sheet according to claim 9,
wherein, in the white polyester film, an intrinsic viscosity is 0.65 to 0.90 dL/g.

13. The solar cell back sheet according to claim 9,
wherein, in the white polyester film, at an equivalent of a thickness of 250 μm, the transverse stretching direction tear strength F_{TD} is 2.0 to 4.0 N.

14. The solar cell back sheet according to claim 9,
wherein the white polyester film is a film roll wound in a roll shape.

15. A solar cell module comprising:
a solar cell element;
a sealing material that seals the solar cell element;
a front substrate disposed on an outside of the sealing material on a light-receiving surface side of the solar cell element; and
a solar cell back sheet including the white polyester film according to claim 1 disposed on an outside of the sealing material on a side opposite to the light-receiving surface side of the solar cell element.

16. The solar cell module according to claim 15,
wherein, in the white polyester film, a peak temperature of tan δ measured using a dynamic viscoelasticity measurement instrument is 122° C. to 133° C.

17. The solar cell module according to claim 15,
wherein, in the white polyester film, a content of the white particles is 2% to 10% by mass with respect to a total mass of the film.

18. The solar cell module according to claim 15,
wherein, in the white polyester film, an intrinsic viscosity is 0.65 to 0.90 dL/g.

19. The solar cell module according to claim 15,
wherein, in the white polyester film, at an equivalent of a thickness of 250 μm, the transverse stretching direction tear strength F_{TD} is 2.0 to 4.0 N.
